(19) United States
(12) Patent Application Publication
(10) Pub. No.: US 2007/0282076 A1
(43) Pub. Date: Dec. 6, 2007

(54) Transition Metal Carbene Complexes Embedded in Polymer Matrices for Use in Oleds

(75) Inventors: Markus Bold, Dirmstein (DE); Martina Egen, Dossenheim (DE); Gerhard Wagenblast, Wachenheim (DE); Klaus Kahle, Ludwigshafen (DE); Christian Lennartz, Schifferstadt (DE); Florian Dotz, Heidelberg (DE); Simon Nord, Romerberg (DE); Hans-Werner Schmidt, Bayreuth (DE); Mukundan Thelakkat, Bayreuth (DE); Wolfgang Kowalsky, Braunschweig (DE); Christian Schildknecht, Braunschweig (DE); Markus Bate, Kulmain (DE); Hans-Hermann Johannes, Braunschweig (DE)

Correspondence Address: OBLON, SPIVAK, MCCLELLAND MAIER & NEUSTADT, P.C., 1940 DUKE STREET, ALEXANDRIA, VA, 22314, US

(73) Assignee: BASF Aktiengesellschaft, Ludwigshafen (DE)

(21) Appl. No.: 11/660,528

(22) PCT Filed: Aug. 17, 2005
(86) PCT No.: PCT/EP05/08913

§ 371 Date: Feb. 20, 2007

(30) Foreign Application Priority Data
Aug. 18, 2004 (DE) 10 2004 040 005.9

(51) Int. Cl. C09K 11/06; C07F 15/00; H01L 51/30; H05B 33/14

(52) U.S. Cl. 525/370

(57) ABSTRACT

The present invention relates to the use of polymeric materials comprising at least one transition metal-carbene complex in organic light-emitting diodes (OLEDs), polymeric materials comprising at least one selected transition metal-carbene complex, a process for preparing the polymeric materials of the invention, a light-emitting layer comprising at least one polymeric material used according to the invention or at least one polymeric material of the invention, an organic light-emitting diode (OLED) comprising the light-emitting layer of the invention and devices comprising the organic light-emitting diode of the invention.

The present invention relates to the use of polymeric materials comprising at least one transition metal-carbene complex in organic light-emitting diodes (OLEDs), polymeric materials comprising at least one selected transition metal-carbene complex, a process for preparing the polymeric materials of the invention, a light-emitting layer comprising at least one polymeric material used according to the invention or at least one polymeric material according to the invention, an organic light-emitting diode (OLED) comprising the light-emitting layer of the invention and devices comprising the organic light-emitting diode of the invention.

Organic light-emitting diodes (OLEDs) exploit the ability of particular materials to emit light when they are excited by an electric current. OLEDs are of particular interest as alternatives to cathode ray tubes and liquid crystal displays for producing flat VDUs. Owing to their very compact construction and their intrinsically low power consumption, devices comprising OLEDs are particularly useful for mobile applications, for example for applications in mobile telephones, laptops etc.

Numerous materials which emit light on excitation by an electric current have been proposed.

For reasons of spin statistics, the energy and power efficiency of triplet emitters is significantly higher than that of singlet emitters. The use of triplet emitters in OLEDs is therefore of interest. The triplet emitters used according to the prior art are generally organic metal complexes. When using these organic metal complexes as light-emitting layer in OLEDs, the organic metal complexes are usually applied by vapor deposition of the organic metal complexes under reduced pressure. However, a vapor deposition process is not optimally suitable for the mass production of OLEDs and is subject to restrictions in respect of the production of devices having large-area displays.

It is therefore desirable to provide polymeric emitter materials which can be applied from solution in the form of a film to produce a light-emitting layer, for example by inkjet printing, spin-coating or dipping, so as to make it possible to produce large-area displays simply and inexpensively. The application of the light-emitting layer in the form of a film is also of interest for the production of full-color displays (RGB displays).

Polymeric materials comprising triplet emitters are thus of particular interest as emitter materials in OLEDs.

WO 03/080687 relates to polymer compounds which have a main polymer chain onto which a metal complex is bound via a spacer. Material displaying a white luminescence can be provided by means of these polymer compounds and luminescence of a desired color can be made possible by means of them. The polymeric compounds are therefore used in OLEDs. Metal complexes used are metal complexes of Ir, Pt, Rh or Pd. These preferably have cyclic nitrogen-containing ligands and also an acetylacetonato ligand via which the complex is bound to the main polymer chain.

DE-A 101 09 027 relates to rhodium and iridium complexes which are functionalized by halogen. These rhodium and iridium complexes are phosphorescent emitters. Owing to their halogen function, the complexes can be functionalized further or be used as (co)monomers in the preparation of appropriate polymers. For example, the functionalized complexes can be copolymerized into polyfluorenes, polyspirobifluorenes, polyparaphenylenes, polycarbazoles or polythiophenes.

EP-A 1 245 659 relates to polymeric light-emitting substances comprising a polystyrene which has a number average molecular weight of from 10³ to 10⁸ and comprises a metal complex displaying light emission from an excited triplet state in the main chain or in the side chain. The use of transition metal-carbene complexes is not mentioned.

It is therefore an object of the present invention to provide polymeric materials which comprise triplet emitters and are suitable as light-emitting layer in OLEDs and can be applied from solution. The materials should be suitable for producing electroluminescence in the blue, red and green regions of the electromagnetic spectrum, thus making production of full-color displays possible.

This object is achieved by the use of polymeric materials comprising
at least one polymer and
at least one transition metal complex of the formula I 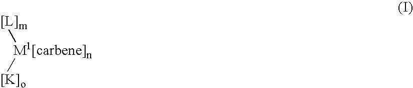
   where the symbols have the following meanings:
M¹ is a metal atom selected from the group consisting of Co, Rh, Ir, Nb, Pd, Pt, Fe, Ru, Os, Cr, Mo, W, Mn, Tc, Re, Cu, Ag and Au in any oxidation state possible for the respective metal atom;
carbene is a carbene ligand which may be uncharged or monoanionic and monodentate, bidentate or tridentate and can also be a biscarbene or triscarbene ligand;
L is a monoanionic or dianionic ligand, preferably a monoanionic ligand, which can be monodentate or bidentate;
K is an uncharged monodentate or bidentate ligand;
n is the number of carbene ligands and is at least 1, with the carbene ligands in the complex of the formula I being able to be identical or different in the case of n>1;
m is the number of ligands L, where m can be 0 or ≧1 and the ligands L can be identical or different in the case of m>1;
o is the number of ligands K, where o can be 0 or ≧1 and the ligands K can be identical or different in the case of o>1;

where the sum n+m+o is dependent on the oxidation state and coordination number of the metal atom used and on the number of coordination sites occupied by each of the ligands carbene, L and K and on the charge on the ligands carbene and L, with the proviso that n is at least 1; where

the at least one polymer is not poly(N-vinylcarbazole) or polysilane;

in organic light-emitting diodes.

For the purposes of the present invention, a bidentate ligand is a ligand which is coordinated at two points to the transition metal atom M¹. In the present patent application, the term “bidentate” is used synonymously with the expression “occupying two coordination sites”.

For the purposes of the present invention, a monodentate ligand is a ligand which is coordinated at one point on the ligand to the transition metal atom M¹.

The polymeric materials used according to the invention can be used as emitter material, with the ligand skeleton, central metal or polymer being able to be varied to produce desired properties of the polymeric materials. The polymeric materials used according to the invention are preferably used as emitter material in OLEDs.

The polymeric materials used according to the invention are highly suitable for use as light-emitting layer in OLEDs. They can be applied from solution, for example by inkjet printing, spin coating or dipping, so that large-area displays can be produced simply and inexpensively with the aid of the polymeric materials used according to the invention. These polymeric materials used according to the invention are likewise of interest for the production of full-color displays (RGB displays).

For the purposes of the present application, polymeric materials include both mixtures comprising at least one transition metal complex of the formula I and at least one polymer and also at least one polymer bound covalently to at least one transition metal complex of the formula I. If the transition metal complex of the formula I is bound covalently to at least one polymer, then at least one, preferably from 1 to 3, particularly preferably 1 or 2, of the ligands L, K and/or carbene has one or more points of linkage, preferably from 1 to 3 points of linkage, particularly preferably 1 or 2 points of linkage, to the polymer. If the complex has more than one point of linkage, the points of linkage can be present on the same ligand L, K or carbene or, if the transition metal complex of the formula I bears more than one ligand L, K or carbene, on various ligands L, K or carbene.

The transition metal complexes of the general formula I particularly preferably have a metal atom M¹ selected from the group consisting of Os, Rh, Ir, Ru, Pd and Pt, with Os(IV), Rh(III), Ir(I), Ir(III), Ru(III), Ru(IV), Pd(II) and Pt(II) being preferred. Metal atoms which are particularly preferably used are Ru, Rh, Ir and Pt, preferably Ru(III), Ru(IV), Rh(III), Ir(I), Ir(II) and Pt(II). Very particular preference is given to using Ir or Pt, preferably Ir(III) or Pt(II), particularly preferably Ir(III), as metal atom M¹.

Suitable monoanionic or dianionic ligands L, preferably monoanionic ligands L, which may be monodentate or bidentate, are the ligands customarily used as monodentate or bidentate monoanionic or dianionic ligands.

Suitable monoanionic monodentate ligands are, for example, halides, in particular Cl⁻ and Br⁻, pseudohalides, in particular CN⁻, cyclopentathenyl (Cp⁻) which may be substituted by alkyl substituents, preferably methyl or tert-butyl, indenyl which may be substituted by alkyl substituents, preferably methyl, alkyl radicals which are bound to the transition metal M¹ via a sigma bond, for example CH₃, alkylaryl radicals which are bound to the transition metal M¹ via a sigma bond, for example benzyl, alkoxides, e.g. OCH₃⁻, trifluorosulfonates, carboxylates, thiolates, amides.

Suitable monoanionic bidentate ligands are, for example, β-diketonates such as acetylacetonate and its derivatives, picolinate, amino acid anions and also the bidentate monoanionic ligands mentioned in WO 02/15645, with acetylacetonate and picolinate being preferred.

Suitable uncharged monodentate or bidentate ligands K are preferably selected from the group consisting of phosphines, preferably trialkylphosphines, triarylphosphines or alkylarylphosphines, particularly preferably PAr₃, where Ar is a substituted or unsubstituted aryl radical and the three aryl radicals in PAr₃ can be identical or different, particularly preferably PPh₃, PEt₃, PnBu₃, PEt₂Ph, PMe₂Ph, PnBu₂Ph; phosphonates and derivatives thereof, arsenates and derivatives thereof, phosphites, CO; pyridines which may be substituted by alkyl or aryl groups; nitriles and thenes which form a π complex with M¹, preferably η⁴-diphenyl-1,3-butathene, η⁴-1,3-pentathene, η⁴-1-phenyl-1,3-pentathene, η⁴-1,4-dibenzyl-1,3-butathene, η⁴-2,4-hexathene, η⁴-3-methyl-1,3-pentathene, η⁴-1,4-ditolyl-1,3-butathene, η⁴-1,4-bis(trimethylsilyl)-1,3-butathene and η²- or η⁴-cyclooctathene (each 1,3 and each 1,5), η²-cyclooctene, particularly preferably 1,4-diphenyl-1,3-butathene, 1-phenyl-1,3-pentathene, 2,4-hexathene, butathene, η²-cyclooctene, η⁴-1,3-cyclooctathene and η⁴-1,5-cyclooctathene.

Particularly preferred uncharged monodentate ligands are selected from the group consisting of PPh₃, P(OPh)₃, AsPh₃, CO, pyridine and nitriles. Suitable uncharged bidentate ligands are particularly preferably η⁴-1,4-diphenyl-1,3-butathene, η⁴-1-phenyl-1,3-pentathene, η⁴-2,4-hexathene, η⁴-cyclooctathene and η²-cyclooctathene (each 1,3 and each 1,5).

Depending on the coordination number of the metal M¹ used and the nature and number of the ligands L, K and carbene used, various isomers of the corresponding metal complexes can be present for the same metal M¹ and the same nature and number of the ligands K, L and carbene used. For example, complexes of a metal M¹ having the coordination number 6 (i.e. octahedral complexes), for example Ir(III) complexes, can have cis/trans isomers when they have the general composition MA₂B₄ or fac/mer isomers (facial/meridional isomers) when they have the general composition MA₃B₃. In the case of square planar complexes of a metal M¹ having the coordination number 4, for example Pt(II) complexes, cis/trans isomers are possible when they have the general composition MA₂B₂. The symbols A and B in each case represent a bonding position of a ligand, with not only monodentate but also bidentate ligands being able to be present.

In the abovementioned general composition, an unsymmetrical bidentate ligand is considered to have one group A and one group B.

A person skilled in the art will be familiar with the term cis/trans and fac/mer isomers. In the case of octahedral complexes, a cis isomer is an isomer of a complex of the composition MA₂B₄ in which the two groups A occupy adjacent corners of an octahedron, while in the case of the trans isomer the two groups A occupy opposite corners of an octahedron. In the case of complexes of the composition of MA₃B₃, three groups of the same type can either occupy the corners of one octahedral face (facial isomer) or a meridian, i.e. two of the three ligand bonding positions are trans relative to one another (meridional isomer). The definition of cis/trans isomers and fac/mer isomers in octahedral metal complexes may be found, for example, in J. Huheey, E. Keiter, R. Keiter, Anorganische Chemie: Prinzipien von Struktur und Reaktivität, 2nd revised edition, translated and expanded by Ralf Steudel, Berlin; N.Y.: de Gruyter, 1995, pages 575, 576.

In the case of square-planar complexes, cis isomers are isomers of complexes of the composition MA₂B₂ in which the two groups A and also the two groups B occupy adjacent corners of a square, while in the case of the trans isomer the two groups A and also the two groups B occupy diagonally opposite corners of a square. The definition of cis/trans isomers in square planar metal complexes may be found, for example, in J. Huheey, E. Keiter, R. Keiter, Anorganische Chemie: Prinzipien von Struktur und Reaktivität, 2nd revised edition, translated and expanded by Ralf Stendel, Berlin; N.Y.: de Gruyter, 1995, pages 557 to 559.

The number n of carbene ligands in transition metal complexes in which the transition metal atom is Ir(III) having a coordination number of 6 is from 1 to 3, preferably 2 or 3, particularly preferably 3. If n>1, the carbene ligands can be identical or different.

The number n of carbene ligands in transition metal complexes in which the transition metal atom is Pt(II) having a coordination number of 4 is 1 or 2, preferably 2. If n>1, the carbene ligands can be identical or different.

The number m of monoanionic ligands L in the abovementioned case is from 0 to 2, preferably 0 or 1, particularly preferably 0. If m>1, the ligands L can be identical or different, but they are preferably identical.

The number o of uncharged ligands K is dependent on whether the coordination number 6 of Ir(III) or 4 of Pt(II) has already been reached by means of the carbene ligands and the ligands L. If, in the case of Ir(III) being used, n is three and three monoanionic bidentate carbene ligands are used, then o is 0 in the abovementioned case. If, in the case of Pt(II) being used, n is two and two monoanionic bidentate carbene ligands are used, then o is likewise 0 in this case.

In the case of at least one transition metal complex of the formula I being bound covalently to the polymer, bonding can be via one or more of the ligands K, L and carbene.

Bonding is preferably via at least one carbene ligand.

Covalent bonding of at least one transition metal complex of the formula I to at least one polymer occurs via one or more suitable points of linkage on the transition metal complex of the formula I to one or more points of linkage on the polymer. A person skilled in the art will know that in the embodiments mentioned below, it is not always the case that 100% of the points of linkage present on the transition metal complex or complexes of the formula I react with 100% of the points of linkage present on the polymer, i.e. incomplete reaction can occur. This means that the embodiments mentioned below of transition metal complexes of the formula I bound covalently to a polymer also encompass embodiments which may have unreacted points of linkage both on the polymer and on the transition metal complex or either on the polymer or on the transition metal complex. In the following embodiments, the idealized case of 100% bonding is presented for reasons of simplicity, but it has to be recognized that 100% bonding generally does not take place, so that unreacted points of linkage can be present in the transition metal complex or complexes of the formula I and/or in the polymer after covalent bonding of the transition metal complex or complexes of the formula I to the polymer.

If bonding to the polymer occurs via more than one point of linkage, in particular 2 or 3 points of linkage, these points of linkage can be located on the same ligand or on different ligands. It is preferred that all points of linkage are located on carbene ligands.

Suitable points of linkage on the polymer or polymers and on the transition metal complex or complexes of the formula I are, for example, selected from the group consisting of halogen such as Br, I or Cl, alkylsulfonyloxy such as trifluoromethanesulfonyloxy, arylsulfonyloxy such as toluenesulfonyloxy, boron-containing radicals, OH, COOH, activated carboxyl radicals such as acid halides, acid anhydrides or esters, —N≡N⁺X⁻, where X⁻ is a halide, e.g. Cl⁻ or Br⁻, SH, SiR₂″X, where X is halogen selected from among F, Cl and Br, and NHR, where R and R″ are each hydrogen, aryl or alkyl, and the abovementioned radicals can be bound directly via a single bond to one of the ligands L, K or carbene, preferably carbene, or to the polymer, or they are bound via a linker —(CR′₂)_{q}—, where the radicals R′ are each, independently of one another, hydrogen, alkyl or aryl and q is from 1 to 15, preferably from 1 to 11, and one or more methylene groups of the linker —(CR′₂)_{q}— can be replaced by —O—, —S—, —N(R)—, —Si(R₂)—, —CON(R)—, —CO—, —C(O)—O—, —O—C(O)—, —CH═CH— or —C—C—, where R is hydrogen, aryl or alkyl, to one of the ligands L, K or carbene, preferably carbene, or to the polymer or via a C₆-C₁₈-arylene group as linker which may be substituted by substituents such as alkyl radicals, aryl radicals, halogen, CN or NO₂. The abovementioned groups are selected so that the respective functional group on the polymer can react with the respective functional group on the transition metal complex or complexes. Suitable combinations capable of reacting are known to those skilled in the art and are described below.

In one embodiment, the polymeric material used according to the invention comprises at least one transition metal complex of the formula IA 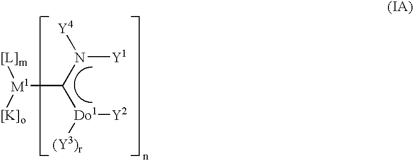
where the symbols have the following meanings:
Do¹ is a donor atom selected from the group consisting of C, N, O, P and S, preferably N, O, P and S, particularly preferably N;
r is 2 when Do¹ is C, is 1 when Do¹ is N or P and is 0 when Do¹ is O or S;
Y¹, Y² are each, independently of one another, hydrogen or a carbon-containing group selected from the group consisting of alkyl, aryl, heteroaryl and alkenyl groups, preferably alkyl and aryl groups,
   or
   Y¹ and Y² together form a bridge between the donor atom Do¹ and the nitrogen atom N which has at least two atoms, preferably two or three atoms, particularly preferably two atoms, of which at least one is a carbon atom and the further atoms are preferably nitrogen or carbon atoms, with the bridge being able to be saturated or unsaturated, preferably unsaturated, and the at least two atoms of the bridge being able to be substituted or unsubstituted; the substituents on the groups Y¹ and Y² can together form a bridge having a total of from three to five, preferably four, atoms of which one or two atoms can be heteroatoms, preferably N, and the remaining atoms are carbon atoms, so that Y¹ and Y² together with this bridge form a five- to seven-membered, preferably six-membered, ring which may have two or in the case of a six- or seven-membered ring three double bonds and may be substituted by alkyl or aryl groups and may contain heteroatoms, preferably N, with preference being given to a six-membered aromatic ring which may be unsubstituted or substituted by alkyl or aryl groups or be fused with further rings which may contain at least one heteroatom, preferably N, preferably with six-membered aromatic rings;
Y³, Y⁴ are each, independently of one another, a hydrogen atom or an alkyl, aryl, heteroaryl or alkenyl radical; preferably hydrogen or an alkyl, heteroaryl or aryl radical,
   where Y¹, Y², Y³ and Y⁴ cannot simultaneously be hydrogen.

The meanings of the symbols M¹, L, K and n, m and o have been given above.

For the purposes of the present patent application, the terms aryl radical or group, heteroaryl radical or group, alkyl radical or group and alkenyl radical or group have the following meanings:

An aryl radical (or group) is a radical which has a basic skeleton of from 6 to 30 carbon atoms, preferably from 6 to 18 carbon atoms, and is made up of an aromatic ring or a plurality of fused aromatic rings. Suitable basic skeletons are, for example, phenyl, naphthyl, anthracenyl or phenanthrenyl. This basic skeleton can be unsubstituted, (i.e. all carbon atoms which are substitutable bear hydrogen atoms) or can be substituted on one, more than one or all substitutable positions of the basic skeleton. Suitable substituents are, for example, alkyl radicals, preferably alkyl radicals having from 1 to 8 carbon atoms, particularly preferably methyl, ethyl or i-propyl, aryl radicals, preferably C₆-C₂₂-aryl radicals, particularly preferably C₆-C₁₈-aryl radicals, very particularly preferably C₆-C₁₄-aryl radicals, i.e. aryl radicals having a phenyl, naphthyl, phenanthrenyl or anthracenyl skeleton, which may in turn be substituted or unsubstituted, heteroaryl radicals, preferably heteroaryl radicals which contain at least one nitrogen atom, particularly preferably pyridyl radicals, alkenyl radicals, preferably alkenyl radicals containing one double bond, particularly preferably alkenyl radicals having one double bond and from 1 to 8 carbon atoms, or groups having a donor or acceptor action. For the purposes of the present invention, groups having a donor action are groups having a +I and/or +M effect, and groups having an acceptor action are groups having a −I and/or −M effect. Suitable groups having a donor or acceptor action are halogen radicals, preferably F, Cl, Br, particularly preferably F, alkoxy radicals, aryloxy radicals, carbonyl radicals, ester radicals, amine radicals, amide radicals, CH₂F groups, CHF₂ groups, CF₃ groups, CN groups, thio groups or SCN groups. The aryl radical or the aryl group is preferably a C₆-C₁₄-aryl radical which may be substituted by at least one of the abovementioned substituents. The C₆-C₁₄-aryl radical particularly preferably bears one or two of the abovementioned substituents. In the case of a C₆-aryl radical bearing one substituent, this is located in the ortho, meta or para position relative to the further point of linkage of the aryl radical and, in the case of two substituents, these can be located in the meta positions or ortho positions relative to the further point of linkage of the aryl radical or one radical is located in the ortho position and one radical is located in the meta position.

A heteroaryl radical or a heteroaryl group is a radical which differs from the abovementioned aryl radicals in that at least one carbon atom in the basic skeleton of the aryl radical is replaced by a heteroatom. Preferred heteroatoms are N, O and S. Very particular preference is given to one or two carbon atoms of the basic skeleton of the aryl radicals being replaced by heteroatoms. The basic skeleton is particularly preferably selected from among systems such as pyridyl and five-membered heteroaromatics such as pyrrole, furans. The basic skeleton can be substituted in one, more than one or all substitutable positions of the basic skeleton. Suitable substituents are the same ones which have been mentioned above for the aryl groups.

An alkyl radical or an alkyl group is a radical having from 1 to 20 carbon atoms, preferably from 1 to 10 carbon atoms, particularly preferably from 1 to 8 carbon atoms. This alkyl radical can be branched or unbranched and may be interrupted by one or more heteroatoms, preferably N, O, Si or S. Furthermore, this alkyl radical can be substituted by one or more of the substituents mentioned for the aryl groups. It is likewise possible for the alkyl radical to bear one or more aryl groups. In this case, all of the abovementioned aryl groups are suitable. The alkyl radicals are particularly preferably selected from the group consisting of methyl and isopropyl.

An alkenyl radical or an alkenyl group is a radical which corresponds to the abovementioned alkyl radicals having at least two carbon atoms, except that at least one C—C single bond of the alkyl radical is replaced by a C—C double bond. The alkenyl radical preferably has one or two double bonds.

A bridge which has at least two atoms of which at least one is a carbon atom and the further atoms are preferably nitrogen or carbon atoms, with the bridge being able to be saturated or preferably unsaturated and the at least two atoms of the bridge being able to be substituted or unsubstituted, is preferably one of the following groups:
a bridge which has two carbon atoms or a carbon atom and a nitrogen atom, with the carbon atoms or a carbon atom and a nitrogen atom being joined by a double bond so that the bridge has one of the following formulae, with the bridge preferably having two carbon atoms: 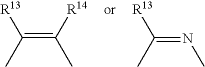
R¹³ and R¹⁴ are each, independently of one another, hydrogen, alkyl or aryl or
R¹³ and R¹⁴ together form a bridge having a total of from 3 to 5, preferably 4, atoms of which one or two may be heteroatoms, preferably N, and the remaining atoms are carbon atoms, so that this group forms a 5- to 7-membered, preferably six-membered, ring which may have, apart from the existing double bond, one or in the case of a six- or seven-membered ring two further double bonds and may be substituted by alkyl or aryl groups or be fused. Preference is given to a six-membered aromatic ring. This may be unsubstituted or substituted by alkyl or aryl radicals. Furthermore, it is possible for one or more further aromatic rings to be fused onto this preferably six-membered, aromatic ring. Any conceivable type of fusion is possible in this case. These fused-on radicals can in turn be substituted, preferably by the radicals mentioned in the general definition of aryl radicals.
A bridge which has two carbon atoms joined to one another by a single bond so that the bridge has the following formula: 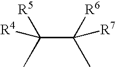
   where R⁴,
R⁵, R⁶
and R⁷ are each, independently of one another, hydrogen, alkyl, aryl, heteroaryl or alkenyl, preferably hydrogen, alkyl or aryl.

In the case of covalent bonding of at least one transition metal complex of the formula IA to the polymer via one or more carbene ligands, bonding can occur via at least one of the radicals Y¹, Y², Y³ or Y⁴ which has at least one point of linkage, preferably from 1 to 3 points of linkage, particularly preferably 1 or 2 points of linkage, to the polymer.

Preference is given to at least one of the radicals Y¹, Y², Y³ or Y⁴ being an aryl or heteroaryl radical which has at least one point of linkage, preferably from 1 to 3 points of linkage, particularly preferably 1 or 2 points of linkage, to the polymer. When Y¹ and Y² form a bridge which is part of an aryl radical, this aryl radical can have from 1 to 3, preferably 1 or 2, points of linkage to the polymer. In the case of more than one point of linkage, the points of linkage of the complex can be present on different radicals Y¹, Y², Y³ or Y⁴, preferably Y³ or Y⁴, or on the same radical. Thus, in the case of two points of linkage, preference is given to one point of linkage being present on each of Y³ and Y⁴ or both points of linkage being present either on Y³ or on Y⁴ or one or both points of linkage being present on an aryl radical formed by Y¹ and Y². It is likewise possible for, for example in the case of two points of linkage, the points of linkage to be present on two different carbene ligands, for example in each case on Y³ or Y⁴ of the respective carbene ligand or in each case on an aryl radical formed by Y¹ and Y² of the respective carbene ligand. However, it is also possible for the two points of linkage to be present on different groups of the respective carbene ligands, for example on Y³ of one carbene ligand and on an aryl radical formed by Y¹ and Y² of the further carbene ligand.

M¹ in the transition metal complex of the formula IA is very particularly preferably Ir(III) or Pt(II), in particular Ir(III).

The group 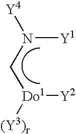
is very particularly preferably selected from the group consisting of 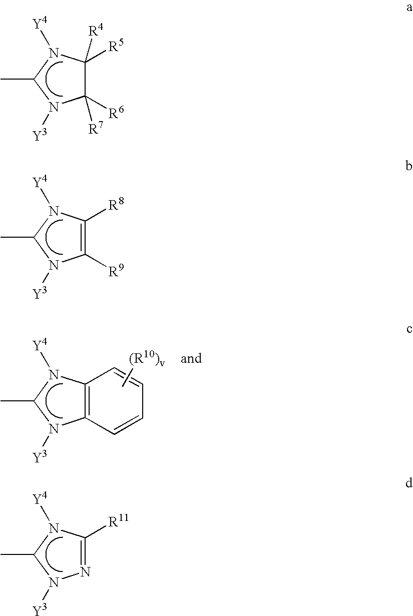
and R¹¹ are each hydrogen, alkyl, aryl, heteroaryl, alkenyl or a substituent having a donor or acceptor action which is preferably selected from among halogen radicals, preferably F, Cl, Br, particularly preferably F, alkoxy radicals, aryloxy radicals, carbonyl radicals, ester radicals, amine radicals, amide radicals, CH₂F groups, CHF₂ groups, CF₃ groups, CN groups, thio groups and SCN groups; where one or two of the radicals R⁴, R⁵, R⁶ or R⁷ in the group of the formula a, one or two of the radicals R⁸ or R⁹ in the group of the formula b and the radical R¹¹ in the group of the formula d can be replaced by one or, in the case of the groups of the formulae a and b, one or two groups capable of bonding covalently to a polymer; with preference being given to one or two of the radicals R⁸ or R⁹ in the group of the formula b and the radical R¹¹ in the group of the formula d being replaced by one or, in the case of the group of the formula b, one or two groups capable of bonding covalently to a polymer;
R¹⁰ is alkyl, aryl, heteroaryl, alkenyl, preferably alkyl, heteroaryl or aryl, or 2 radicals R¹⁰ together form a fused-on ring which may contain at least one heteroatom, preferably N, with preference being given to 2 radicals R¹⁰ together forming a fused-on aromatic C₆ ring, where one or more further aromatic rings may be fused onto this, preferably six-membered, aromatic ring, with any conceivable type of fusion being possible, and the fused-on radicals can in turn be substituted; or R¹⁰ is a radical having a donor or acceptor action which is preferably selected from among halogen radicals, preferably F, Cl, Br, particularly preferably F; alkoxy groups, aryloxy groups, carbonyl groups, ester groups, amino groups, amide radicals, CHF₂, CH₂F, CF₃, CN, thio groups and SCN;
v is from 0 to 4, preferably 0, 1 or 2, very particularly preferably 0, where, when v is 0, all 4 possible substituents of the aryl radical in the formula c are hydrogen atoms and the aryl radical of the group of the formula c may bear, in addition to any radicals R¹⁰ present, one or two groups capable of bonding covalently to a polymer.

The radicals Y³ and Y⁴ have been defined above.

In a further preferred embodiment of the present invention, the at least one carbene ligand in the uncharged transition metal complexes of the general formula I is a bidentate and/or monoanionic carbene ligand. The at least one carbene ligand is very particularly preferably a monoanionic bidentate carbene ligand.

The carbene ligand or ligands in the transition metal complex of the formula I very particularly preferably has/have the formula (II) 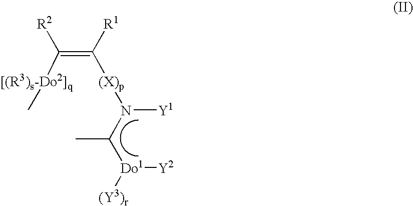
where the symbols have the following meanings:
Do¹ is a donor atom selected from the group consisting of C, P, N, O and S, preferably P, N, O and S, particularly preferably N;
Do² is a donor atom selected from the group consisting of C, N, P, O and S;
r is 2 when Do¹ is C, is 1 when Do¹ is N or P and is 0 when Do¹ is O or S;
s is 2 when Do² is C, is 1 when Do² is N or P and is 0 when Do² is O or S;
X is a spacer selected from the group consisting of silylene, alkylene, arylene, heteroarylene or alkenylene, preferably alkylene or arylene, particularly preferably C₁-C₃-alkylene or C₆-1,4-arylene in which at least one of the four further carbon atoms may be substituted by methyl, ethyl, n-propyl or i-propyl groups or by groups having a donor or acceptor action selected from among halogen radicals, preferably F, Cl, Br, particularly preferably F, alkoxy radicals, aryloxy radicals, carbonyl groups, ester groups, amino groups, amide radicals, CHF₂, CH₂F, CF₃, CN, thio groups and SCN, very particularly preferably methylene, ethylene or 1,4-phenylene;
p is 0 or 1, preferably 0;
q is 0 or 1, preferably 0;
Y¹, Y² are each, independently of one another, hydrogen or a carbon-containing group selected from the group consisting of alkyl, aryl, heteroaryl and alkenyl groups; preferably alkyl, heteroaryl and aryl groups,
   or
   Y¹ and Y² together form a bridge between the donor atom Do¹ and the nitrogen atom N which has at least two atoms, preferably two or three atoms, particularly preferably two atoms, of which at least one is a carbon atom and the at least one further atom is preferably a nitrogen atom, with the bridge being able to be saturated or unsaturated, preferably unsaturated, and the at least two atoms of the bridge being able to be substituted or unsubstituted; the substituents on the groups Y¹ and Y² can together form a bridge having a total of from three to five, preferably four, atoms of which one or two atoms can be heteroatoms, preferably N, and the remaining atoms are carbon atoms, so that Y¹ and Y² together with this bridge form a five- to seven-membered, preferably six-membered, ring which may have two or in the case of a six- or seven-membered ring three double bonds and may be substituted by alkyl or aryl groups and may contain heteroatoms, preferably N, with preference being given to a six-membered aromatic ring which is unsubstituted or substituted by alkyl or aryl groups or is fused with further rings which may contain at least one heteroatom, preferably N, preferably with six-membered aromatic rings;
Y³ is a hydrogen atom or an alkyl, aryl, heteroaryl or alkenyl radical, preferably a hydrogen atom or an alkyl, heteroaryl or aryl radical
   or 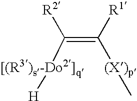
   where Do^{2′}, q′, s′, R^{3′}, R^{1′}, R^{2′}, X′ and p′ independently have the same meanings as Do², q, s, R³, R¹, R², X and p;
R¹, R² are each, independently of one another, hydrogen or an alkyl, aryl, heteroaryl or alkenyl radical, preferably hydrogen or an alkyl radical, heteroaryl radical or aryl radical;
   or
   R¹ and R² together form a bridge having a total of from three to five, preferably four, atoms of which one or two atoms can be heteroatoms, preferably N, and the remaining atoms are carbon atoms, so that the group 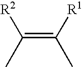
   forms a five- to seven-membered, preferably six-membered, ring which may have, apart from the existing double bond, one or in the case of a six- or seven-membered ring two further double bonds and may be substituted by alkyl or aryl groups and may contain heteroatoms, preferably N, with preference being given to a six-membered aromatic ring which is unsubstituted or substituted by alkyl or aryl groups or is fused with further rings which may contain at least one heteroatom, preferably N, preferably six-membered aromatic rings;
R³ is hydrogen or an alkyl, aryl, heteroaryl or alkenyl radical, preferably hydrogen or an alkyl, heteroaryl or aryl radical. Preference is given to ligands of the formula II in which p and/or q are/is 0, i.e. no spacers X and/or no donor atoms Do² are present in the ligands of the formula II.

The group 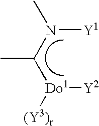
is preferably selected from the group consisting of 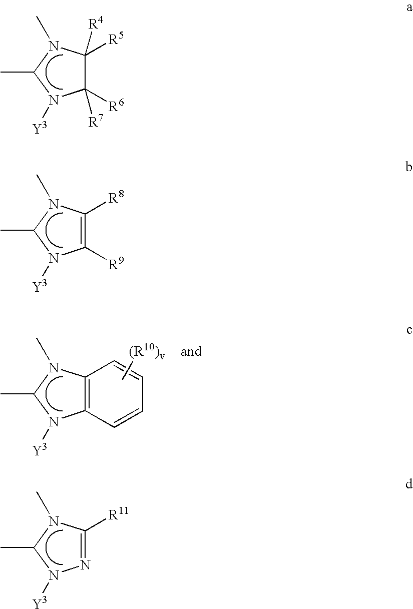
where the symbols have the following meanings:
R⁴, R⁵, R⁶,
R⁷, R⁸, R⁹
and R¹¹ are each hydrogen, alkyl, aryl, heteroaryl, alkenyl or a substituent having a donor or acceptor action which is selected from among halogen radicals, preferably F, Cl, Br, particularly preferably F, alkoxy radicals, aryloxy radicals, carbonyl radicals, ester radicals, amine radicals, amide radicals, CH₂F groups, CHF₂ groups, CF₃ groups, CN groups, thio groups and SCN groups, preferably hydrogen, alkyl, heteroaryl or aryl; where one or two of the radicals R⁴, R⁵, R⁶ or R⁷ in the group of the formula a, one or two of the radicals R⁸ or R⁹ in the group of the formula b and the radical R¹¹ in the group of the formula d can be replaced by one or, in the case of the groups of the formulae a and b, one or two groups capable of bonding covalently to a polymer; with preference being given to one or two of the radicals R⁸ or R⁹ in the group of the formula b and the radical R¹¹ in the group of the formula d being replaced by one or, in the case of the group of the formula b, one or two groups capable of bonding covalently to a polymer;
R¹⁰ is alkyl, aryl, heteroaryl, alkenyl, preferably alkyl or aryl, or 2 radicals R¹⁰ together form a fused-on ring which may contain at least one heteroatom, preferably N, with preference being given to 2 radicals R¹⁰ together forming a fused-on aromatic C₆ ring, where one or more further aromatic rings may be fused onto this, preferably six-membered, aromatic ring, with any conceivable type of fusion being possible, and the fused-on radicals can in turn be substituted; or R¹⁰ is a radical having a donor or acceptor action which is preferably selected from the group consisting of halogen radicals, preferably F, Cl, Br, particularly preferably F; alkoxy groups, aryloxy groups, carbonyl groups, ester groups, amino groups, amide radicals, CHF₂, CH₂F, CF₃, CN, thio groups and SCN;
v is from 0 to 4, preferably 0, 1 or 2, very particularly preferably 0, where, when v is 0, the four carbon atoms of the aryl radical in the formula c which may be substituted by R¹⁰ bear hydrogen atoms and the aryl radical of the group of the formula c may bear, in addition to any radicals R¹⁰ present, one or two groups capable of bonding covalently to a polymer,
Y³ has been defined above.

The group 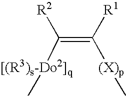
of the carbene ligand of the formula II is preferably 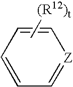
where the symbols have the following meanings:
Z is CH or N, with Z being able to be located in the o, m or p position relative to the point of linkage of the group to the carbene ligand;
R¹² is an alkyl, aryl, heteroaryl or alkenyl radical, preferably an alkyl or aryl radical, or 2 radicals R¹² together form a fused-on ring which may contain at least one heteroatom, preferably N, with preference being given to 2 radicals R¹² together forming a fused-on aromatic C₆ ring, where one or more further aromatic rings may be fused onto this, preferably six-membered, aromatic ring, with any conceivable type of fusion being possible, and the fused-on radicals can in turn be substituted; or R¹² is a radical having a donor or acceptor action which is preferably selected from the group consisting of halogen radicals, preferably F, Cl, Br, particularly preferably F; alkoxy groups, aryloxy groups, carbonyl groups, ester groups, amino groups, amide radicals, CHF₂, CH₂F, CF₃, CN, thio groups and SCN;
t is from 0 to 3, where, when t>1, the radicals R¹² can be identical or different, with preference being given to t being 0 or 1, and the group can bear one or two groups capable of bonding covalently to a polymer in addition to any radicals R¹² present.

In the carbene ligands of the formula II, Y³ can be identical to or different from the above-defined group and have the following meanings which have been mentioned above:

a hydrogen atom or an alkyl, aryl, heteroaryl or alkenyl radical, preferably a hydrogen atom or an alkyl, heteroaryl or aryl radical or 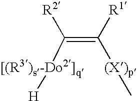
where Do^{2′}, q′, s′, R^{3′}, R^{1′}, R^{2′}, X′ and p′ independently have the same meanings as Do², q, s, R³, R¹, R², X and p.

Apart from carbene ligands of the formula II in which Y⁴, i.e. the group of the formula 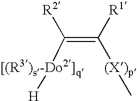
has the structure 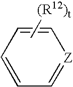
and Y³ is 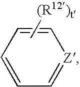
further suitable carbene ligands are ones in which Y⁴, i.e. the group of the formula 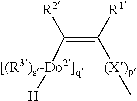
has the structure 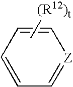
and Y³

is a hydrogen atom or an alkyl, aryl, heteroaryl or alkenyl radical, preferably a hydrogen atom or an alkyl, heteroaryl or aryl radical.

The definitions of the symbols correspond to the definitions given above.

When at least one transition metal complex of the formula IA is bound to the polymer, bonding is preferably via one or more of the carbene ligands of the formula II which have at least one radical of the formula 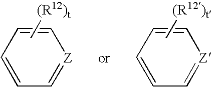
as radical Y³ or Y⁴, with this at least one radical having at least one point of linkage in the polymer. If the transition metal complex of the formula IA is bound via one point of linkage, this is present either on the radical 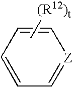
or on the radical

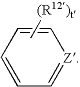

In the case of two points of linkage, both points of linkage can be present on the same radical or each can be present on one of the abovementioned radicals, which is preferred. It is likewise possible for the two points of linkage to be present on two different carbene ligands. They can in each case be present on the same radical, for example in each case on the radical Y³, in the different carbene ligands, or on different radicals, for example on the radical Y³ in one carbene ligand and on the radical Y⁴ in the other carbene ligand.

The at least one carbene ligand of the formula II is very particularly preferably selected from the group consisting of 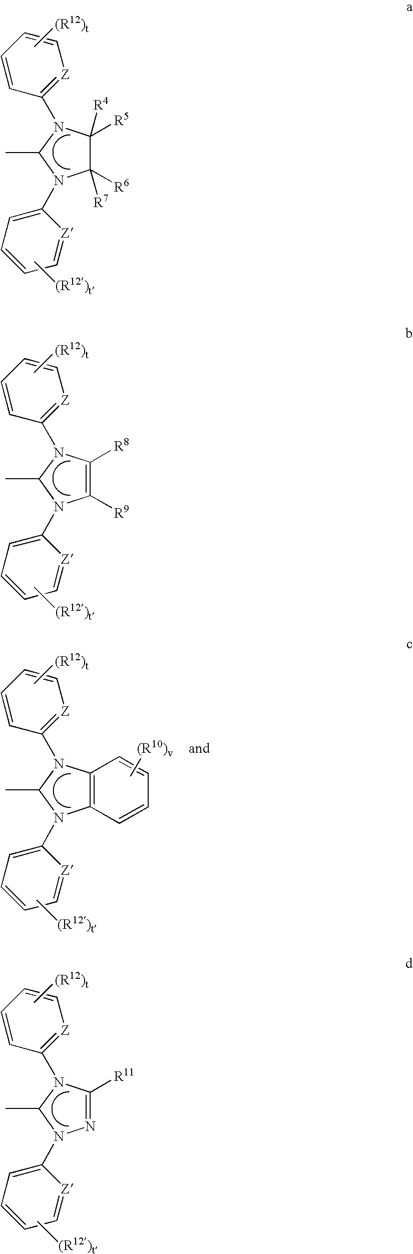
where the symbols have the following meanings:
Z, Z′ are identical or different and are each CH or N;
R¹², R^{12′} are identical or different and are each an alkyl, aryl, heteroaryl or alkenyl radical, preferably an alkyl or aryl radical, or 2 radicals R¹² or R^{12′} together form a fused-on ring which may contain at least one heteroatom, preferably N, with preference being given to 2 radicals R¹² or R^{12′} together forming a fused-on aromatic C₆ ring, where one or more further aromatic rings may be fused onto this, preferably six-membered, aromatic ring, with any conceivable type of fusion being possible, and the fused-on radicals can in turn be substituted; or R¹² or R^{12′} is a radical having a donor or acceptor action, which is preferably selected from the group consisting of halogen radicals, preferably F, Cl, Br, particularly preferably Br or F; alkoxy groups, aryloxy groups, carbonyl groups, ester groups, amino groups, amide radicals, CHF₂, CH₂F, CF₃, CN, aryloxy groups, thio groups and SCN;
t and t′ are identical or different, preferably identical, and are each from 0 to 3, where, when t or t′>1, the radicals R¹² or R^{12′} can be identical or different; t or t′ is preferably 0 or 1 and when t or t′ is 1, the radical R¹² or R^{12′} is located in the ortho, meta or para position relative to the point of linkage to the nitrogen atom adjacent to the carbene carbon atom; where the aryl radicals which may bear the radicals R¹² and R^{12′} can bear one or two groups capable of bonding covalently to a polymer in addition to any radicals R¹² and R^{12′} present;
R⁴, R⁵, R⁶,
R⁷, R⁸, R⁹
and R¹¹ are each hydrogen, alkyl, aryl, heteroaryl, alkenyl or a substituent having a donor or acceptor action which is preferably selected from among halogen radicals, preferably F, Cl, Br, particularly preferably F, alkoxy radicals, aryloxy radicals, carbonyl radicals, ester radicals, amine radicals, amide radicals, CH₂F groups, CHF₂ groups, CF₃ groups, CN groups, thio groups and SCN groups, preferably hydrogen, alkyl, heteroaryl or aryl; where one or two of the radicals R⁴, R⁵, R⁶ or R⁷ in the group of the formula a, one or two of the radicals R⁸ or R⁹ in the group of the formula b and the radical R¹¹ in the group of the formula d can be replaced by one or, in the case of the groups of the formulae a and b, one or two groups capable of bonding covalently to a polymer; with preference being given to one or two of the radicals R⁸ or R⁹ in the group of the formula b and the radical R¹¹ in the group of the formula d being replaced by one or, in the case of the group of the formula b, one or two groups capable of bonding covalently to a polymer;
R¹⁰ is alkyl, aryl, heteroaryl or alkenyl, preferably alkyl, heteroaryl or aryl, or 2 radicals R¹⁰ together form a fused-on ring which may contain at least one heteroatom, preferably nitrogen, with preference being given to 2 radicals R¹⁰ together forming a fused-on aromatic C₆ ring, where one or more further aromatic rings may be fused onto this, preferably six-membered, aromatic ring, with any conceivable type of fusion being possible, and the fused-on radicals can in turn be substituted; or R¹⁰ is a radical having a donor or acceptor action which is preferably selected from the group consisting of halogen radicals, preferably F, Cl, Br, particularly preferably F; alkoxy groups, aryloxy groups, carbonyl groups, ester groups, amino groups, amide radicals, CHF₂, CH₂F, CF₃, CN, thio groups and SCN;
v is from 0 to 4, preferably 0, 1 or 2, very particularly preferably 0, where, when v is 0, the four carbon atoms of the aryl radical in the formula c which may be substituted by R¹⁰ bear hydrogen atoms and the aryl radical of the group of the formula c may bear, in addition to any radicals R¹⁰ present, one or two groups capable of bonding covalently to a polymer.

Preferred transition metal complexes of the formula (I) are thus ones comprising at least one carbene ligand of the formula II, with preferred embodiments of the carbene ligand of the formula II having been mentioned above.

Particularly preferred transition metal complexes of the general formula are therefore ones having the general formula (IB)

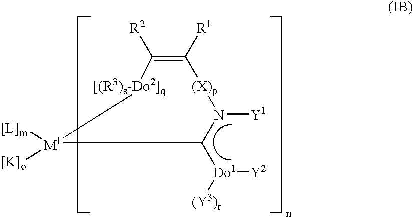

The meanings of the symbols correspond to the meanings given above in respect of the transition metal complex (I) and in respect of the carbene ligand (II). Preferred embodiments have likewise been mentioned above.

The transition metal complexes of the formula IB can, when a metal atom M¹ having the coordination number 6 is used, be present as facial or meridional isomer or as an isomer mixture of facial and meridional isomers in any ratios when they have the composition MA₃B₃, as mentioned above. Depending on the properties of the facial or meridional isomer of the transition metal complexes of the formula IB, it can be preferable to use either an isomerically pure facial isomer or an isomerically pure meridional isomer or an isomer mixture of facial and meridional isomers in which one of the isomers is present in excess or the isomers are present in equal amounts. For example, facial and meridional isomers of the transition metal complex of the formula IB are possible when n is 3 and m and o are each 0. When the transition metal complexes of the formula IB have the composition MA₂B₄, the transition metal complexes can be present in the form of cis/trans isomers in any ratios, as mentioned above. Depending on the properties of the cis or trans isomer of the transition metal complexes of the formula IB, it can be preferable to use either an isomerically pure cis isomer or an isomerically pure trans isomer or an isomer mixture of cis and trans isomers in which one of the isomers is present in excess or the isomers are present in equal amounts. cis/trans isomers of complexes of the formula IB are, for example, possible when M¹ is a metal atom having the coordination number 6 and when n is 2 and m is 2, with the two monodentate ligands L being identical, and o is 0, or when o is 2 and the two monodentate ligands K are identical, and m is 0.

The transition metal complexes of the formula IB can, when a metal atom M¹ which has the coordination number 4 and forms square planar complexes is used, be present as cis or trans isomers or as an isomer mixture of cis and trans isomers in any ratios when they have the composition MA₂B₂, as mentioned above. For example, cis/trans isomers of the transition metal complexes of the formula IB are possible when n is 2 and m and o are each 0.

In the case of transition metal complexes in which the transition metal atom is Ir(III) having a coordination number of 6, the number of the preferred monoanionic bidentate carbene ligands n is at least 1 and not more than 3. The number of the monoanionic bidentate carbene ligands which are preferably used is preferably 2 or 3, particularly preferably 3. When n>1, the carbene ligands can be identical or different. In the case of transition metal complexes in which the transition metal atom is Pt(II) having a coordination number of 4, the number of monoanionic bidentate ligands n is 1 or 2, preferably 2.

Very particular preference is given to a transition metal complex in which M¹ is Ir(III) having a coordination number of 6. In this Ir(III) complex, very particular preference is given to n being 3, m being 0, o being 0, q being 0, p being 0, Do¹ being N and r being 1, with the other symbols having the meanings indicated above.

Especial preference is given to transition metal complexes of the formulae IBa to d selected from the group consisting of 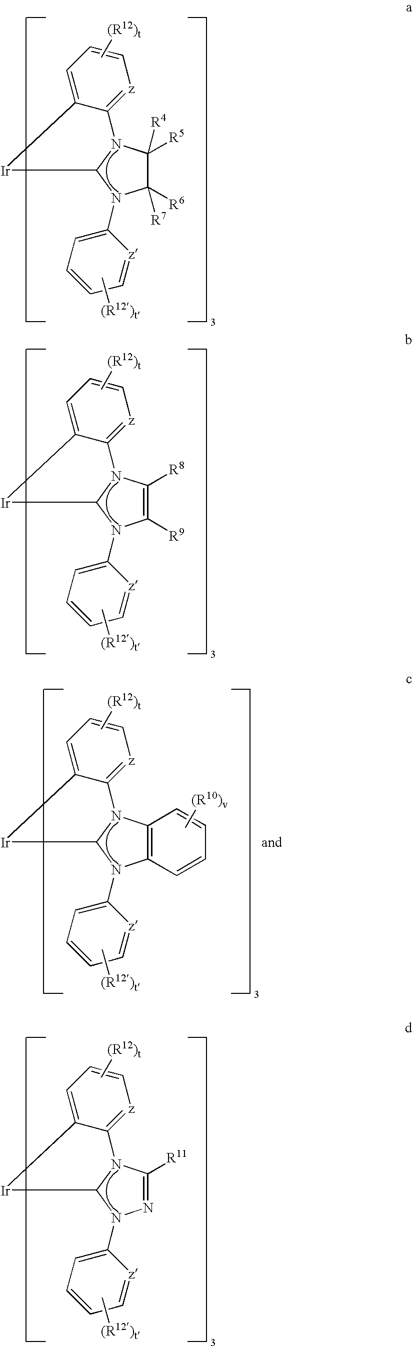
where the symbols have the meanings given above in respect of the preferred carbene ligands. In the case of the complexes of the formulae IBa to d, it has to be noted that the three ligands present on the Ir(III) can be identical or different and in the case of a covalent bond, at least one ligand is different from the two further ligands. In particular, they can differ in terms of whether or not they have a point of linkage to a polymer or the position in which the respective point of linkage is present on the ligand when the complexes of the formulae IBa to d have more than one point of linkage.

Among these Ir(III) complexes, very particular preference is given to those of the formulae b, c and d. Especial preference is given to Ir(III) complexes of the formulae b and c in which Z and Z′ are each CH, R⁸ and R⁹ are each H or alkyl, t, t′ and v are each 0 and the other radicals have the meanings given above in respect of the preferred carbene ligands. When the complex is bound covalently to a polymer, one or more of the alkyl radicals which may bear the radicals R¹², R^{12′} and R¹⁰ can bear one or two groups capable of bonding to the polymer.

Bonding to the polymer is preferably via at least one of the radicals 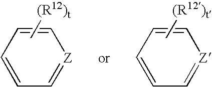
as mentioned above.

Suitable polymers are, for example, poly-p-phenylene-vinylene and its derivatives, polythiophene and its derivatives, polyfluorene and its derivatives, polyfluoranthene and its derivatives and also polyacetylene and its derivatives, polystyrene and its derivatives, poly(meth)acrylates and derivatives thereof, e.g. polymethyl methacrylate. Particular preference is given to polyfluoranthene and its derivatives, polyfluorene and its derivatives and poly-p-phenylene-vinylene and its derivatives and poly(meth)acrylates and derivatives thereof, e.g. polymethyl methacrylate. Further suitable polymers are copolymers comprising monomer units of the polymers mentioned. Here, the copolymers can comprise various monomer units of the polymers mentioned, for example copolymers made up of fluorene and fluoranthene units, and the copolymers can also be made up of monomer units of one or more of the polymers mentioned together with further suitable monomer units known to those skilled in the art. The preparation of the homopolymers and copolymers mentioned is known to those skilled in the art. In the following, the term polymers encompasses both homopolymers and copolymers.

In a preferred embodiment, the present invention provides for the use of polymeric materials comprising at least one transition metal complex of the formula I which is covalently bound to a polymer. The covalent bonding of the transition metal complex or complexes to the polymer or polymers can be of any type known to those skilled in the art. For example, the transition metal complex or complexes can be covalently bonded directly to the polymer, for example via a single bond, a double bond or an —O—, —S—, —N(R)—, —CON(R)—, —N═N—, —CO—, —C(O)—O— or —O—C(O)— group, where R is hydrogen, alkyl or aryl.

On the other hand, bonding via a linker is also possible, for example via a C₁-C₁₅-alkylene group, preferably a C₁-C₁₁-alkylene group, where one or more methylene groups of the alkylene group can be replaced by —O—, —S—, —N(R)—, —Si(R₂)—, —CON(R)—, —CO—, —C(O)—O—, —O—C(O)—, —N═N—, —CH═CH— or —C≡C— to form a chemically feasible radical and the alkylene group can be substituted by substituents such as alkyl radicals, aryl radicals, halogen, CN or NO₂, where R is hydrogen, alkyl or aryl; or via a C₆-C₁₈-arylene group which may be substituted by substituents such as alkyl radicals, aryl radicals, halogen, CN or NO₂.

The polymeric materials used according to the invention can be prepared in various ways.
a) Polymeric materials which comprise a mixture comprising at least one transition metal complex of the formula I and at least one polymer are generally prepared by mixing the individual components. Suitable mixing apparatuses and mixing methods are known to those skilled in the art. For example, a defined amount of transition metal complex of the formula I can be mixed with a solution of a suitable polymer. Suitable polymers have been mentioned above. Suitable solvents for preparing the solution of the polymer depend on the polymer used and are known to those skilled in the art. Removal of the solvent gives the polymeric material which is used according to the invention and comprises a mixture of the transition metal complex of the formula I with a suitable polymer. As an alternative, the transition metal complex and the polymer can be mixed with one another in the solid state without addition of solvents.

In the polymeric materials used according to the invention which comprise mixtures comprising at least one transition metal complex of the formula I and at least one polymer, the amount of transition metal complex is dependent on whether or not the polymer used itself displays electroluminescence. If the polymer used itself displays electroluminescence, the amount of transition metal complex of the formula I is generally from 0.5 to 50% by weight, preferably from 1 to 30% by weight, particularly preferably from 1 to 20% by weight, based on the total amount of polymer and transition metal complex of the formula I. If the polymer used does not itself display electroluminescence, the amount of transition metal complex of the formula I is generally from 5 to 50% by weight, preferably from 10 to 40% by weight, particularly preferably from 15 to 35% by weight. The total amount of polymer and transition metal complex of the formula I is 100% by weight.

The polymer used generally has a molecular weight of from 10² to 10⁶, preferably from 10³ to 5×10⁵, particularly preferably 10⁴ to 3×10⁵, measured by GPC (gel permeation chromatography using polystyrene standards).
b) The preparation of the polymeric materials used according to the invention in which at least one transition metal complex of the formula I is bound covalently to at least one polymer can be carried out by the following methods:
ba) reaction of at least one functionalized polymer
   “polymer”−(T)_{p′}
   with at least one transition metal complex of the formula III functionalized with one or more groups Q, where Q is covalently bound to a ligand K, a ligand L or a carbene ligand, preferably to a carbene ligand, 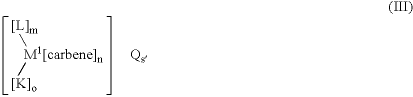
   where the symbols have the following meanings:
   M¹ is a metal atom selected from the group consisting of Co, Rh, Ir, Nb, Pd, Pt, Fe, Ru, Os, Cr, Mo, W, Mn, Tc, Re, Cu, Ag and Au in any oxidation state possible for the respective metal atom;
   carbene is a carbene ligand which may be uncharged or monoanionic and monodentate, bidentate or tridentate and can also be a biscarbene or triscarbene ligand;
   L is a monoanionic or dianionic ligand, preferably a monoanionic ligand, which can be monodentate or bidentate;
   K is an uncharged monodentate or bidentate ligand selected from the group consisting of phosphines, preferably trialkylphosphines, triarylphosphines or alkylarylphosphines, particularly preferably PAr₃, where Ar is a substituted or unsubstituted aryl radical and the three aryl radicals in PAr₃ can be identical or different, particularly preferably PPh₃, PEt₃, PnBu₃, PEt₂Ph, PMe₂Ph, PnBu₂Ph; phosphonates and derivatives thereof, arsanes and derivatives thereof, phosphites, CO; pyridines which may be substituted by alkyl or aryl groups; nitriles and dienes which form a π complex with M¹, preferably η⁴-diphenyl-1,3-butadiene, η⁴-1,3-pentadiene, η⁴-1-phenyl-1,3-pentadiene, η⁴-1,4-dibenzyl-1,3-butadiene, η⁴-2,4-hexadiene, η⁴-3-methyl-1,3-pentadiene, η⁴-1,4-ditolyl-1,3-butadiene, η⁴-1,4-bis(trimethylsilyl)-1,3-butadiene and η²- or η⁴-cyclooctadiene (each 1,3 and each 1,5), particularly preferably 1,4-diphenyl-1,3-butadiene, 1-phenyl-1,3-pentadiene, 2,4-hexadiene, butadiene, η²-cyclooctene, η⁴-1,3-cyclooctadiene and η⁴-1,5-cyclooctadiene;
   n is the number of carbene ligands and is at least 1, with the carbene ligands in the complex of the formula I being able to be identical or different in the case of n>1;
   m is the number of ligands L, where m can be 0 or ≧1 and the ligands L can be identical or different in the case of m>1;
   o is the number of ligands K, where o can be 0 or ≧1 and the ligands K can be identical or different in the case of o>1;
   where the sum n+m+o is dependent on the oxidation state and coordination number of the metal atom used and on the number of coordination sites occupied by each of the ligands carbene, L and K and on the charge on the ligands carbene and L, with the proviso that n is at least 1; and
   Q and T are radicals capable of being linked to one another to form a covalent bond, where the radical Q is covalently bound to one of the ligands L, K or carbene, preferably to carbene, and the radical T is covalently bound to an end group or central unit of the polymer;
   s′ is an integer from 1 to 3, where in the case of s′>1 the group Q is bound to the same ligand or different ligands K, L or carbene, preferably carbene;
   p′ is the number of radicals T in the polymer, with p′ being dependent on the molecular weight of the polymer and p′ being selected so that the amount of the transition metal complex used is generally from 0.5 to 50% by weight, preferably from 1 to 30% by weight, particularly preferably from 1 to 20% by weight, based on the total amount of polymer and transition metal complex, when the polymer itself displays electroluminescence, and when the polymer does not itself display electroluminescence, the amount of the transition metal complex is generally from 5 to 50% by weight, preferably from 10 to 40% by weight, particularly preferably from 15 to 35% by weight, based on the total amount of polymer and transition metal complex.

Preferred definitions of the symbols K, L, M¹, carbene, m, n and o have been mentioned above. Furthermore, preferred points of linkage to the carbene ligands have been mentioned above, and the radical Q in the transition metal complex of the formula III occupies these points of linkage.

Suitable functionalized polymers are selected from the group consisting of polyfluoranthenes, polyfluorenes, poly-p-phenylene-vinylenes, polyacetylene, polycarbazoles, polythiophenes, polystyrene, poly(meth)acrylates, in particular polymethyl methacrylate, and derivatives of the polymers mentioned which are functionalized with at least one functional group T. The functionalized polymers can be homopolymers or copolymers, as has been mentioned above.

The functionalized polymer used generally has a molecular weight of from 10² to 10⁶, preferably from 10³ to 5×10⁵, particularly preferably from 10⁴ to 3×10⁵, measured by GPC (using polystyrene standards).

Preferred transition metal complexes are transition metal complexes of the formulae IIIAa to d: 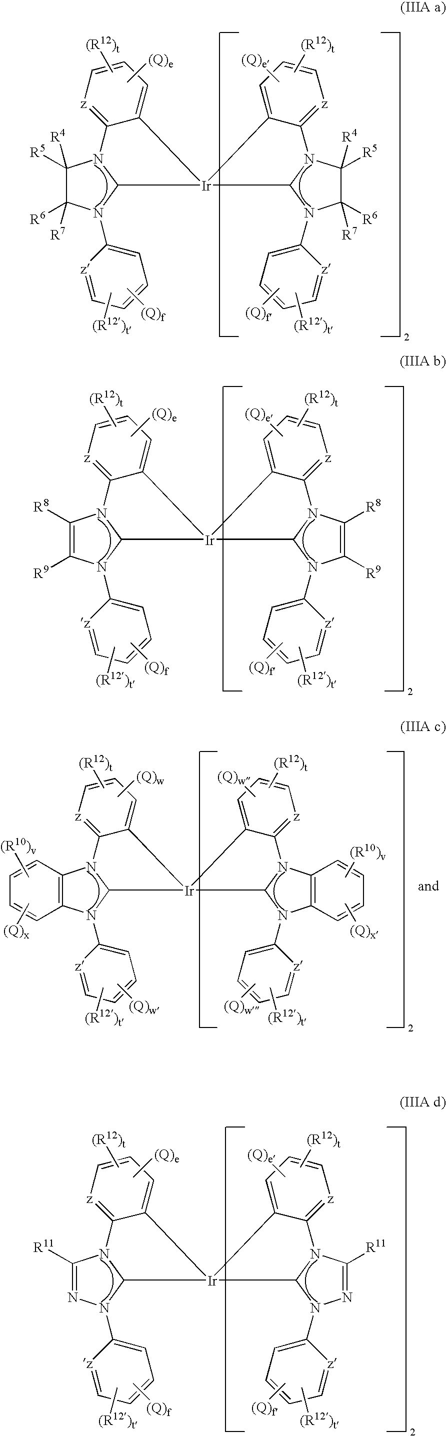
where the symbols R⁴, R⁵, R⁶, R⁷, R¹⁰, R¹¹, R¹², R^{12′}, Y³, V, t, t′, z and z′ have the meanings mentioned above, and one or two of the radicals R⁴, R⁵, R⁶ or R⁷ in the complex of the formula IIIA a, one or two of the radicals R⁸ or R⁹ in the complex of the formula IIIA b and the radical R¹¹ in the complex of the formula IIIA d can be replaced by a group Q or, in the case of the complexes of the formulae IIIA a and IIIA b, one or two groups Q capable of bonding covalently to a polymer; and
the sum of all groups Q in the respective complexes of the formulae IIIA a, IIIA b, IIIAc and IIIA d is in each case s′, i.e. e, f, e′, f′ and the number of radicals R⁴, R⁵, R⁶, R⁷, R⁸, R⁹ and R¹¹ which may be replaced by Q are each 0, 1, 2 or 3 in the complexes of the formulae IIIAa, IIIAb and IIIAd, with the sum of the groups Q in the respective complexes being s′; and w, w′, w″, w′″, x and x′ in the complex of the formula IIIAc are each 0, 1, 2 or 3, with the sum of the groups Q in the complex being s′;
Q is a radical capable of forming a bond to the functionalized polymer;
   where the carbene ligands on Ir(III) which may bear the groups Q can be identical or different. In particular, it is possible for only one of the carbene ligands to bear one or more groups Q while the other carbene ligand bears no group Q. Alternatively, it is possible for two or three carbene ligands each to bear one or more groups Q but in different positions.

Particular preference is given to transition metal complexes of the formulae IIIAb and IIIAc.

The functional group T of the functionalized polymer used and the definition of the radical Q are dependent on the desired form of bonding. Suitable forms of covalent bonds between the transition metal complex and the polymer have been mentioned above.

Q and the functional group or groups T on the functionalized polymer are preferably selected from the group consisting of halogen such as Br, I or Cl, alkylsulfonyloxy such as trifluoromethanesulfonyloxy, arylsulfonyloxy such as toluenesulfonyloxy, boron-containing radicals, OH, COOH, activated carboxyl radicals such as acid halides, acid anhydrides or esters, —N≡N⁺X⁻, where X⁻ is a halide, e.g. Cl⁻ or Br⁻ , SH, SiR₂″X, where X is halogen selected from among F, Cl and Br, and NHR, where R and R″ are each hydrogen, aryl or alkyl, and the abovementioned radicals can be bound directly via a single bond to one of the ligands L, K or carbene, preferably carbene, or to the polymer, or via a linker, —(CR′₂)_{q}—, where the radicals R′ are each, independently of one another, hydrogen, alkyl or aryl and q is from 1 to 15, preferably from 1 to 11, and one or more methylene groups of the linker —(CR′₂)_{q}— can be replaced by —O—, —S—, —N(R)—, —Si(R₂)—, —CON(R)—, —CO—, —C(O)—O—, —O—C(O)—, —CH═CH— or —C≡C—, where R is hydrogen, aryl or alkyl, to one of the ligands L, K or carbene, preferably carbene, or the polymer; or via a C₆-C₁₈-arylene group as linker which may be substituted by substituents such as alkyl radicals, aryl radicals, halogen, CN, or NO₂. The abovementioned groups are selected so that the respective functional group on the polymer can react with the respective functional group Q on the transition metal complex or complexes. Suitable combinations of groups which can react with one another are known to those skilled in the art.

For example, the transition metal complex can be bound to the polymer via an ester linkage when Q in the formula III is either OH or COOH and the functionalized polymer correspondingly bears OH or COOH as functional groups T.

Furthermore, the transition metal complex can be bound to the polymer by means of an amide linkage when Q is an activated carboxyl radical, for example an acid halide, preferably an acid chloride radical, an acid anhydride radical or an ester radical or NHR and the functionalized polymer correspondingly bears at least one activated carboxyl radical, for example an acid halide radical, preferably acid chloride radical, an acid anhydride radical or an ester radical or NHR, as functional groups T. R is hydrogen, alkyl or aryl.

Furthermore, bonding of the transition metal complex to the polymer can be achieved by means of azo coupling, in which case either Q or T is —N≡N⁺X⁻, where X⁻ is a halide, for example Cl⁻ or Br⁻. The other group T or Q is hydrogen. It has to be noted that coupling of the diazonium salt occurs with an electron-rich aromatic. Suitable electron-rich aromatics and their preparation and also the preparation of suitable diazonium salts are known to those skilled in the art.

Furthermore, the transition metal complex can be bound to the polymer via a single bond which can be formed by means of a coupling reaction. Suitable coupling reactions are known to those skilled in the art. For example, coupling by means of Kumada coupling, Negishi coupling, Yamamoto coupling or by means of a Suzuki reaction in the presence of nickel or palladium compounds is possible. In this case, Q and the functional group T of the functionalized polymer are selected from among halogen, alkylsulfonyloxy, arylsulfonyloxy or a boron-containing radical.

The boron-containing radical is preferably a boron-containing radical of the formula —B(O—[C(R¹⁵)₂]ₙ—O or B(OR¹⁶)₂, where the radicals R¹⁵ and R¹⁶ are in each case identical or different and are, independently of one another, H or C₁-C₂₀-alkyl, n is an integer from 2 to 10, with preference being given to the radicals R¹⁵ and R¹⁶ in each case being identical or different and each being hydrogen or methyl, ethyl, n-propyl, isopropyl, n-butyl, isobutyl, sec-butyl, tert-butyl, n-pentyl, isopentyl, sec-pentyl, neopentyl, 1,2-dimethylpropyl, isoamyl, n-hexyl, isohexyl, sec-hexyl, n-heptyl, isoheptyl, n-octyl, n-decyl, n-dodecyl or n-octadecyl, preferably C₁-C₁₂-alkyl such as methyl, ethyl, n-propyl, isopropyl, n-butyl, isobutyl, sec-butyl, tert-butyl, n-pentyl, isopentyl, sec-pentyl, neopentyl, 1,2-dimethylpropyl, isoamyl, n-hexyl, isohexyl, sec-hexyl or n-decyl, particularly preferably C₁-C₄-alkyl such as methyl, ethyl, n-propyl, isopropyl, n-butyl, isobutyl, sec-butyl or tert-butyl, very particularly preferably methyl; and n preferably being an integer from 2 to 5. Very particular preference is given to boron-containing radicals of the formula
—B(O—[C(CH₃)₂]₂)—O.

In a preferred embodiment, the polymeric materials used according to the invention in which the transition metal complex of the formula I is bound covalently to a polymer are prepared by means of a coupling reaction, preferably by means of Kumada coupling, Negishi coupling, Yamamoto coupling or by means of the Suzuki reaction in the presence of nickel or palladium compounds.

The nickel or palladium compounds are particularly preferably in the oxidation state 0 or, in the case of palladium, in a mixture of Pd(II) salt and a ligand, e.g. Pd(ac)₂ and PPh₃. Very particular preference is given to using the commercially available tetrakis(triphenylphosphine)palladium [Pd(P(C₆H₅)₃)₄] and commercially available nickel compounds, e.g. Ni(C₂H₄)₃, Ni(1,5-cyclooctathene)₂ (“Ni(cod)₂”), Ni(1,6-cyclodecathene)₂ or Ni(1,5,9-all-trans-cyclodecathene)₂. Especial preference is given to using [Pd(P(C₆H₅)₃)₄] and Ni(cod)₂. To carry out the coupling reaction, an excess of P(C₆H₅)₃ or 1,5-cyclooctathene, depending on the catalyst used, can be added.

When carrying out the Negishi coupling in the presence of palladium or nickel compounds, it is usually sufficient to use catalytic amounts, i.e. from 0.1 to 10 mol %, of Pd or Ni, based on the amount of transition metal complex of the formula III used. A coupling reaction between a halide and an organozinc compound which is usually obtained by a reaction of a halide with Zn dust or by reaction of a lithiated species with zinc chloride. In the case of the Negishi coupling, Q and T are therefore halogen, with either the transition metal complex or the polymer being reacted with Zn dust before the actual coupling reaction. Alternatively, Q or T is halogen and the other radical is Li which is reacted with zinc chloride.

When carrying out the Suzuki coupling, it is usual to use from 0.1 to 10 mol % of Pd, based on the amount of transition metal complex of the formula III used. A coupling reaction occurs between a boron-containing compound, preferably a boron-containing compound having a radical of the formula —B(O—[C(CH₃)₂]₂—O), or between a boronic acid or a dialkyl borate and a halide. In the case of the Suzuki coupling, Q is therefore halogen and T is a boron-containing radical, or T is halogen and Q is a boron-containing radical. Q or T can also be alkylsulfonyl or arylsulfonyl instead of halogen in the Suzuki coupling.

The Kumada coupling is generally carried out in the presence of from 0.1 to 10 mol % of Ni or Pd, based on the amount of transition metal complex of the formula III used. A coupling reaction occurs between a halide and a Grignard compound which is usually prepared by reaction of a halide with magnesium. In the case of the Kumada coupling, Q and T are therefore halogen, with either the functionalized transition metal complex or the functionalized polymer being reacted with magnesium before the actual coupling reaction.

When carrying out the Yamamoto coupling, it is usual to use stoichiometric amounts of the Ni coupling reagent, preferably Ni(cod)₂, based on the amount of transition metal complex of the formula III used. However, the reaction can also be carried out catalytically when the Ni(halogen)₂ salt formed is, for example, reduced again by means of activated zinc and thus returned to the circuit. A coupling reaction occurs between two halides. In the case of the Yamamoto coupling, Q and T are therefore halogen. Q or T can also be alkylsulfonyl or arylsulfonyl instead of halogen in the Yamamoto coupling.

The coupling reactions are generally carried out in an organic solvent, e.g. in toluene, ethylbenzene, meta-xylene, ortho-xylene, dimethylformamide (DMF), tetrahydrofuran, dioxane or mixtures of the abovementioned solvents. The solvent or solvents is/are freed of traces of moisture by customary methods prior to the coupling reaction.

In general, the coupling reactions are carried out under protective gas, with nitrogen or noble gases, in particular argon, being suitable for this purpose.

In the coupling reactions which are carried out in the presence of a base, in particular in the Suzuki coupling, use is made of, for example, organic amines, in particular triethylamine, pyridine or collidine.

It is likewise possible for the coupling reactions which are carried out in the presence of a base, preferably the Suzuki coupling, to be carried out in the presence of basic salts, e.g. alkali metal hydroxide, alkali metal alkoxide, alkali metal phosphate, alkali metal carbonate or alkali metal bicarbonate, if appropriate in the presence of a crown ether such as 18-crown-6. Furthermore, the coupling reaction can be carried out as a two-phase reaction using aqueous solutions of alkali metal carbonate, if appropriate in the presence of a phase transfer catalyst. In this case, it is not necessary to free the organic solvent of moisture prior to the reaction. Alkoxides or hydroxides are also suitable as bases.

The coupling reactions usually take from 10 minutes to 2 days, preferably from 2 hours to 24 hours. The pressure conditions are noncritical, and atmospheric pressure is preferred. In general, the coupling reactions are carried out at elevated temperature, preferably in the range from 80° C. to the boiling point of the organic solvent or solvent mixture. The molar ratio of the sum of the radicals Q of the functionalized transition metal complex to the radicals T of the functionalized polymer is generally from 1:1 to 30:1, preferably from 1:1 to 15:1, particularly preferably from 1.2:1 to 6:1.

The functionalized polymer can bear one or more functional groups T. This means that a plurality of singly or multiply functionalized transition metal complexes of the formula III can be bound to one or more multiply functionalized polymers. The molar ratio of the functionalized polymers to the singly or multiply functionalized transition metal complex is therefore dependent on the number of functionalized transition metal complexes to be bound to a particular number of functionalized polymers and on the number of points of linkage on the polymers and the transition metal complexes.

The functionalized polymers used can be prepared by methods known to those skilled in the art.

The functionalized metal complexes of the formula III which are used can likewise be prepared by methods known to those skilled in the art. Suitable processes for preparing them are described, for example, in the review articles W. A. Hermann et al., Advances in Organometallic Chemistry, Vol. 48, 1 to 69, W. A. Hermann et al., Angew. Chem. 1997, 109, 2256 to 2282 and G. Bertrand et al., Chem. Rev. 2000, 100, 39 to 91, and the references cited therein.

In one embodiment, the functionalized transition metal complexes of the formula III are prepared by deprotonation of the ligand precursors corresponding to the respective carbene ligands and subsequent reaction with suitable metal complexes comprising the desired metal. It is also possible to prepare the transition metal complexes by direct use of Wanzlick olefins.

Suitable ligand precursors are known to those skilled in the art. They are preferably cationic precursors.

Suitable processes for preparing the transition metal complexes of the formula III are carried out in a manner analogous to the processes for preparing transition metal complexes disclosed in the PCT application entitled “Übergangsmetallkomplexe mit Carbenliganden als Emitter für organische Licht-emittierende Dioden (OLEDs)” and having the number “ . . . ” which was filed simultaneously with the present patent application and is therefore not a prior publication. In the preparation, it has to be ensured that one of the ligands K, L or carbene, preferably carbene, bears a radical Q.

Two processes for preparing carbene ligands of compounds of the formula III in which Q is Br are shown by way of example in schemes 1 and 2 below:

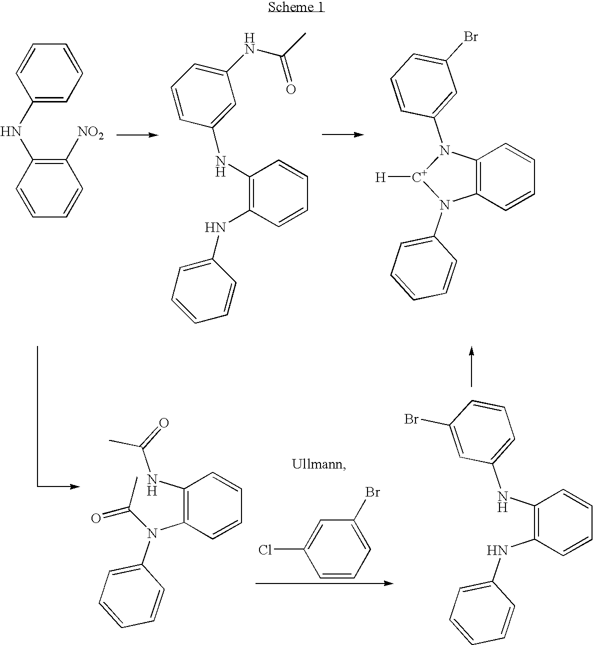

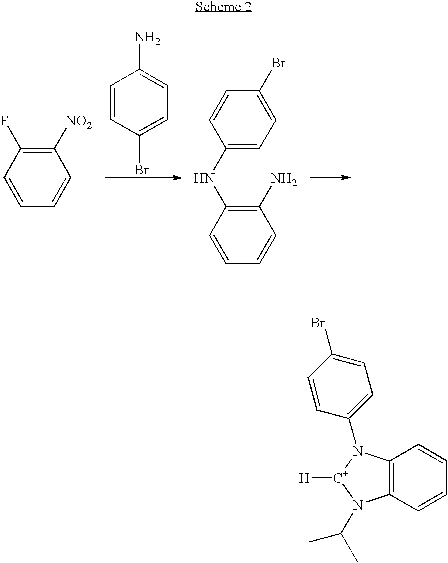

The reaction conditions for preparing the ligands shown in schemes 1 and 2 are known to those skilled in the art.
bb)

The preparation of the polymeric materials which are used according to the invention and comprise a transition metal complex of the formula I bound covalently to a polymer can be effected by introducing a transition metal compound of the formula III into a functionalized polymer and also by introducing at least one transition metal-carbene complex having a bifunctional or trifunctional unit into the main chain of a polymer. In this case, the synthesis is generally not a reaction of an existing functionalized polymer but the preparation of a polymer in the presence of at least one transition metal complex having a bifunctional or trifunctional unit.

The present invention therefore further provides for the use of polymeric materials comprising at least one transition metal complex of the formula I which is covalently bound to a polymer, which can be prepared by copolymerization of monomers having polymerization-active groups with comonomers of the formula IV in which S is bound to one or more ligands K, L or carbene, preferably carbene, 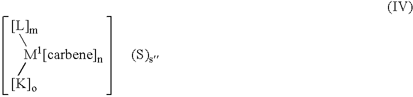
where the symbols have the following meanings:
M¹ is a metal atom selected from the group consisting of Co, Rh, Ir, Nb, Pd, Pt, Fe, Ru, Os, Cr, Mo, W, Mn, Tc, Re, Cu, Ag and Au in any oxidation state possible for the respective metal atom;
carbene is a carbene ligand which may be uncharged or monoanionic and monodentate, bidentate or tridentate and can also be a biscarbene or triscarbene ligand;
L is a monoanionic or dianionic ligand, preferably a monoanionic ligand, which can be monodentate or bidentate;
K is an uncharged monodentate or bidentate ligand;
n is the number of carbene ligands and is at least 1, with the carbene ligands in the complex of the formula I being able to be identical or different in the case of n>1;
m is the number of ligands L, where m can be 0 or ≧1 and the ligands L can be identical or different in the case of m>1;
o is the number of ligands K, where o can be 0 or ≧1 and the ligands K can be identical or different in the case of o>1;
   where the sum n+m+o is dependent on the oxidation state and coordination number of the metal atom used and on the number of coordination sites occupied by each of the ligands carbene, L and K and on the charge on the ligands carbene and L, with the proviso that n is at least 1;
S is a group which can be polymerized with the polymerization-active groups of the monomers and is bound to one of the ligands L, K or carbene, preferably carbene;
s″ is an integer from 1 to 3, where, when s″>1, the group S is bound to the same ligand or different ligands K, L or carbene, preferably carbene.

In one embodiment, the group S can be bound to the same carbene ligand in the transition metal complex of the formula IV or to different carbene ligands in the transition metal complex of the formula IV.

Preference is given to transition metal complexes of the formulae IVA a to d, where the group S is bound to the same carbene ligand or to different carbene ligands: 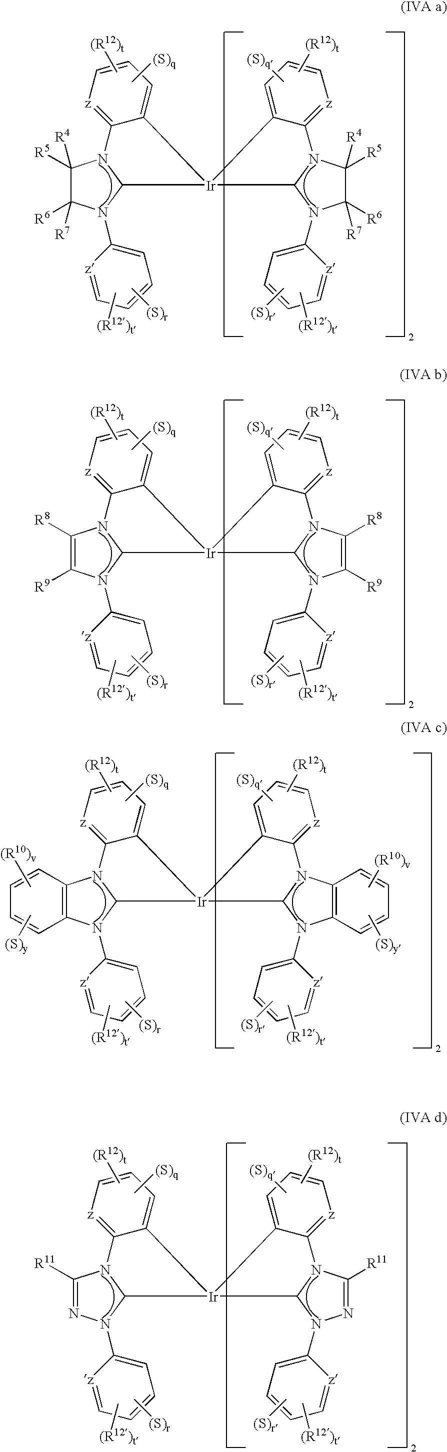
where the symbols R⁴, R⁵, R⁶, R¹⁰, R¹¹, R¹², R^{12′}, Y³, v, t, t′, z and z′have the meanings given above, and
S is a group which can be polymerized with the polymerization-active groups of the monomers, and
q, r, y,
q′, r′,
y′ are each from 0 to 3, where q+r+y+q′+r+y′=s″ and s″ is an integer from 1 to 3,
   with the two carbene ligands on Ir(III), which may bear the groups (S)_{q′}, (S)_{r′} and/or (S)_{y′}, being able to be identical or different. In particular, it is possible for only one of the two carbene ligands to bear one or more groups S, while the other carbene ligand does not bear a group S. Alternatively, it is possible for each of the two carbene ligands to bear one or more groups S, but in different positions; for example, so that q′ is 0 and r′ is 1 in one carbene ligand and q′ is 1 and r′ is 0 in the other carbene ligand.

Particular preference is given to transition metal complexes of the formulae IVAb and IVAc.

For the purposes of the present invention, polymerization-active groups and groups which can be polymerized with the polymerization-active groups are all groups which can be polymerized with one another. The polymerization-active groups and the groups S which can be polymerized with the polymerization-active groups are preferably selected from the group consisting of formyl groups, phosphonium groups, halogen groups such as Br, I, Cl, vinyl groups, acryloyl groups, methacryloyl groups, halomethyl groups, acetonitrile groups, alkylsulfonyloxy groups such as trifluoromethanesulfonyloxy groups, arylsulfonyloxy groups such as toluenesulfonyloxy groups, aldehyde groups, OH groups, alkoxy groups, COOH groups, activated carboxyl groups such as acid halides, acid anhydrides or esters, alkylphosphonate groups, sulfonium groups and boron-containing radicals, preferably halogen groups, alkylsulfonyl groups, arylsulfonyloxy groups, cyclic olefin groups and boron-containing groups.

The polymerization-active groups mentioned above can in each case be bound directly via a single bond to one of the ligands L, K or carbene, preferably carbene, or via a linker —(CR′₂)_{q″}—, where the radicals R′ are each, independently of one another, hydrogen, alkyl or aryl and q″ is from 1 to 15, preferably from 1 to 11, and one or more methylene groups of the linker —(CR′₂)_{q″}— can be replaced by —O—, —S—, —N(R)—, —Si(R₂)—, —CON(R)—, —CO—, —C(O)—O—, —O—C(O)—, —CH═CH— or —C≡—C—, where R is hydrogen, aryl or alkyl, or via a C₆-C₁₈-arylene group as linker which may be substituted by substituents such as alkyl radicals, aryl radicals, halogen, CN or NO₂. Suitable combinations of linkers and polymerization-active groups are known to those skilled in the art. The above-mentioned groups are selected so that the respective polymerization-active groups on the transition metal complex can react with the respective polymerization-active groups of the monomers used. Suitable combinations capable of reacting are known to those skilled in the art.

Suitable boron-containing radicals are the boron-containing radicals mentioned above in the definition of Q.

Suitable polymerization processes for preparing the polymeric materials used according to the invention are mentioned below:
copolymerization by reaction of aldehyde groups with phosphonium salt groups in a Wittig reaction;
copolymerization of aldehyde groups with alkylphosphonate groups in a Horner-Wadsworth-Emmons reaction;
copolymerization by reaction of vinyl groups with halide groups in a Heck reaction;
polycondensation of two halomethyl groups in a dehydrohalogenation;
polycondensation by reaction of two sulfonium salt groups in a method for the decomposition of sulfonium salts;
copolymerization of aldehyde groups with —CH₂CN groups in a Knoevenagel reaction;
copolymerization of two or more aldehyde groups in a McMurry reaction.

Further suitable polymerization methods are the following polymerization processes:
copolymerization in a Suzuki coupling, a Kumada coupling or Yamamoto coupling;
copolymerization using an oxidant such as FeCl₃;
electropolymerization;
ring-opening methathesis polymerization (ROMP).

Among the abovementioned polymerization methods, preference is given to the Wittig reaction, the Heck reaction, the Horner-Wadsworth-Emmons reaction, the Knoevenagel reaction, the Suzuki coupling, the Kumada coupling and the Yamamoto coupling. The copolymerization is particularly preferably effected by means of the Suzuki reaction, the Yamamoto coupling or the Kumada coupling. Suitable combinations of polymerization-active groups and groups which can be polymerized with the polymerization-active groups are known to those skilled in the art.

Suitable combinations (in each case A and B) of polymerization-active groups of the monomers and groups S on the transition metal complexes which can be polymerized with the polymerization-active groups for the case where each monomer has two polymerization-active groups and the transition metal complex has two groups S (s=2) are:

| A | B |
|---|---|
| aldehyde groups | phosphonium salt groups |
| vinyl groups | halide groups |
| aldehyde groups | alkylphosphonate groups |
| halomethyl groups | halomethyl groups |
| sulfonium salt groups | sulfonium salt groups |
| aldehyde groups | —CH₂CN groups |
| aldehyde groups | aldehyde groups |
| halide groups | halide groups |
| boron-containing groups, with preferred | halide groups |
| boron-containing groups having been | |
| mentioned above | |
| alkylsulfonyl groups | arylsulfonyl groups |

Here, each monomer and each transition metal complex can have one group A and one group B or each monomer or each transition metal complex has two groups A and each transition metal complex or each monomer has two groups B.

The reaction conditions for the copolymerizations mentioned are likewise known to those skilled in the art. Reaction conditions for the particularly preferred Suzuki reaction, Kumada coupling and Yamamoto coupling are the same as have been mentioned under ba). Suitable process conditions for the Suzuki reaction are also described, for example, in WO 00/53656, and suitable process conditions for the Yamamoto coupling are also described, for example, in U.S. Pat. No. 5,708,130.

Preferred polymerization-active groups and groups S which can be polymerized with the polymerization-active groups are selected from among halogen groups, alkylsulfonyloxy groups, arylsulfonyloxy groups and boron-containing groups. Preferred embodiments of the groups mentioned have been mentioned above.

The copolymerization of monomers having polymerization-active groups with comonomers of the formula IV which have groups S which can be polymerized with the polymerization-active groups is preferably carried out in the presence of a nickel or palladium catalyst. Preferred nickel and palladium catalysts have been described above under ba), as have suitable amounts of the catalysts.

Furthermore, a free-radical polymerization of monomers having an ethylenically unsaturated group with transition metal complexes having an ethylenically unsaturated group as group S (s=1) is also possible. Preferred ethylenically unsaturated groups are vinyl groups, acryloyl groups and methacryloyl groups.

Suitable reaction conditions for the free-radical polymerization are known to those skilled in the art. Suitable process conditions are described, for example, in EP-A 0 637 899, EP-A 0 803 171 and WO 96/22005.

The ratio of monomers having polymerization-active groups to the transition metal complexes of the formula IV which have groups S which can be polymerized with the polymerization-active groups is selected so that the amount of the transition metal complex is generally from 0.5 to 50% by weight, preferably from 1 to 30% by weight, particularly preferably from 1 to 20% by weight, based on the total amount of polymer and transition metal complex, when the polymer used itself displays electroluminescence. If the polymer used does not itself display electroluminescence, the amount of the transition metal complex is generally from 5 to 50% by weight, preferably from 10 to 40% by weight, particularly preferably from 15 to 35% by weight, based on the total amount of polymer and transition metal complex. The total amount of polymer and transition metal complex is 100% by weight.

The functionalized metal complexes of the formula IV which are used can be prepared by methods known to those skilled in the art. Suitable processes for preparing them are described, for example, in the review articles W. A. Hermann et al., Advances in Organometallic Chemistry, Vol. 48, 1 to 69, W. A. Hermann et al., Angew. Chem. 1997, 109, 2256 to 2282 and G. Bertrand et al., Chem. Rev. 2000, 100, 39 to 91, and the references cited therein.

In one embodiment, the functionalized transition metal complexes of the formula IV are prepared by deprotonation of the ligand precursors corresponding to the respective carbene ligands and subsequent reaction with suitable metal complexes comprising the desired metal. In addition, the transition metal complexes can be prepared by direct use of Wanzlick olefins.

Suitable ligand precursors are known to those skilled in the art. They are preferably cationic precursors.

Suitable processes for preparing the transition metal complexes of the formula IV are carried out in a manner analogous to the processes for preparing transition metal complexes disclosed in the PCT application entitled “Übergangsmetallkomplexe mit Carbenliganden als Emitter für organische Licht-emittierende Dioden (OLEDs)” and having the number . . . which was filed simultaneously with the present patent application and is therefore not a prior publication. In the preparation, it has to be ensured that one or more of the ligands K, L or carbene, preferably carbene, bear radicals S.

A process for preparing carbene ligands of compounds of the formula IV in which S is OTf is shown by way of example in scheme 3 below:

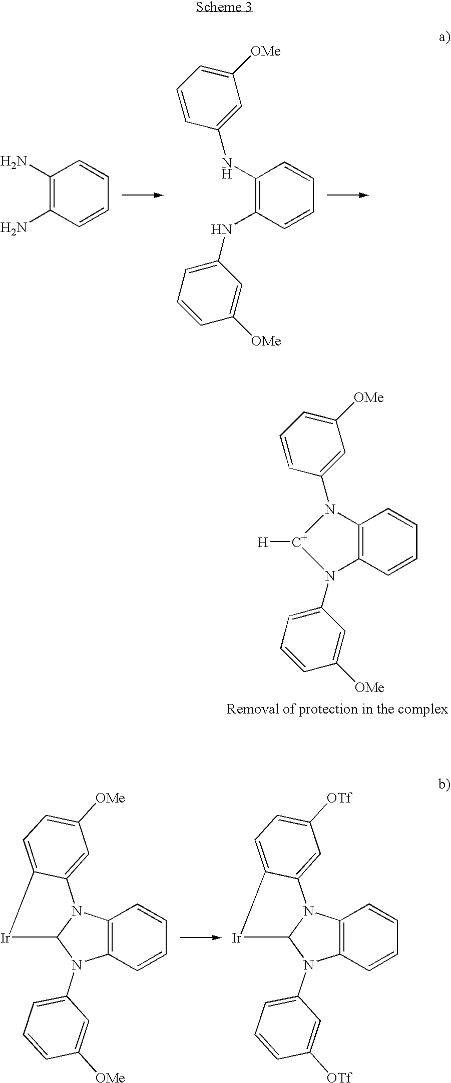

Suitable reaction conditions for preparing the ligand in accordance with scheme 3 are known to those skilled in the art.

The polymeric materials used according to the invention are particularly suitable for use in organic light-emitting diodes. These organic materials are triplet emitters which have a high energy and power efficiency. Incorporation of the triplet emitters into a polymer makes it possible to apply the polymeric materials used according to the invention in the form of a film from solution, e.g. by spin coating, inkjet printing or dipping. Thus, the polymeric materials used according to the invention make it possible to produce large-area displays simply and inexpensively.

The present invention further provides polymeric materials comprising
at least one polymer selected from the group consisting of poly-p-phenylene-vinylene and its derivatives, polythiophene and its derivatives, polyfluorene and its derivatives, polyfluoranthene and its derivatives and also polyacetylene and its derivatives and also polyacetylene and its derivatives, polystyrene and its derivatives, poly(meth)acrylates and derivatives thereof, and copolymers comprising monomer units of the polymers mentioned; and
at least one transition metal complex of the formula 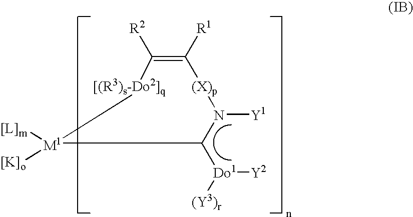
   where the symbols have the following meanings:
M¹ is a metal atom selected from the group consisting of Co, Rh, Ir, Nb, Pd, Pt, Fe, Ru, Os, Cr, Mo, W, Mn, Tc, Re, Cu, Ag and Au in any oxidation state possible for the respective metal atom;
L is a monoanionic or dianionic ligand, preferably a monoanionic ligand, which can be monodentate or bidentate;
K is an uncharged monodentate or bidentate ligand;
n is the number of carbene ligands and is at least 2, with the carbene ligands in the complex of the formula I being able to be identical or different;
m is the number of ligands L, where m can be 0 or ≧1 and the ligands L can be identical or different in the case of m>1;
o is the number of ligands K, where o can be 0 or ≧1 and the ligands K can be identical or different in the case of o>1;
   where
   the sum n+m+o is dependent on the oxidation state and coordination number of the metal atom used and on the number of coordination sites occupied by each of the ligands carbene, L and K and on the charge on the ligands carbene and L, with the proviso that n is at least 2;
Do¹ is a donor atom selected from the group consisting of C, P, N, O and S, preferably P, N, O and S, particularly preferably N;
Do² is a donor atom selected from the group consisting of C, N, P, O and S;
r is 2 when Do¹ is C, is 1 when Do¹ is N or P and is 0 when Do¹ is O or S;
s is 2 when Do² is C, is 1 when Do² is N or P and is 0 when Do² is O or S;
X is a spacer selected from the group consisting of silylene, alkylene, arylene, heteroarylene or alkenylene, preferably alkylene or arylene, particularly preferably C₁-C₃-alkylene or C₆-1,4-arylene in which at least one of the four further carbon atoms may be substituted by methyl, ethyl, n-propyl or i-propyl groups or by groups having a donor or acceptor action selected from among halogen radicals, preferably F, Cl, Br, particularly preferably F, alkoxy radicals, aryloxy radicals, carbonyl groups, ester groups, amino groups, amide radicals, CHF₂, CH₂F, CF₃, CN, thio groups and SCN, very particularly preferably methylene, ethylene or 1,4-phenylene;
p is 0 or 1, preferably 0;
q is 0 or 1, preferably 0;
Y¹, Y² together form a bridge between the donor atom Do¹ and the nitrogen atom N which has at least two atoms, preferably two or three atoms, particularly preferably two atoms, of which at least one is a carbon atom and the at least one further atom is preferably a nitrogen atom, with the bridge being able to be saturated or unsaturated, preferably unsaturated, and the at least two atoms of the bridge being able to be substituted or unsubstituted, in which case, if the bridge has two carbon atoms and is saturated, at least one of the two carbon atoms is substituted; the substituents on the groups Y¹ and Y² can together form a bridge having a total of from three to five, preferably four, atoms of which one or two atoms can be heteroatoms, preferably N, and the remaining atoms are carbon atoms, so that Y¹ and Y² together with this bridge form a five- to seven-membered, preferably six-membered, ring which may have two or in the case of a six- or seven-membered ring three double bonds and may be substituted by alkyl or aryl groups and may contain heteroatoms, preferably N, with preference being given to a six-membered aromatic ring which is unsubstituted or substituted by alkyl or aryl groups or is fused with further rings which may contain at least one heteroatom, preferably N, preferably with six-membered aromatic rings;
Y³ is a hydrogen atom or an alkyl, aryl, heteroaryl or alkenyl radical, preferably a hydrogen atom or an alkyl, heteroaryl or aryl radical
   or 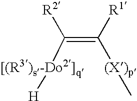
   where Do^{2′}, q′, s′, R^{3′}, R^{1′}, R^{2′}, X′ and p′ independently have the same meanings as Do², q, s, R³, R¹, R², X and p;
R¹, R² are each, independently of one another, hydrogen or an alkyl, aryl, heteroaryl or alkenyl radical, preferably hydrogen or an alkyl radical, heteroaryl radical or aryl radical;
   or
   R¹ and R² together form a bridge having a total of from three to five, preferably four, atoms of which one or two atoms can be heteroatoms, preferably N, and the remaining atoms are carbon atoms, so that the group 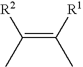
   forms a five- to seven-membered, preferably six-membered, ring which may have, apart from the existing double bond, one or in the case of a six- or seven-membered ring two further double bonds and may be substituted by alkyl or aryl groups and may contain heteroatoms, preferably N, with preference being given to a six-membered aromatic ring which is unsubstituted or substituted by alkyl or aryl groups or is fused with further rings which may contain at least one heteroatom, preferably N, preferably with six-membered aromatic rings;
R³ is hydrogen or an alkyl, aryl, heteroaryl or alkenyl radical, preferably hydrogen or an alkyl, heteroaryl or aryl radical;
   where the at least one polymer can be present in the form of a mixture with the transition metal complex of the formula IB or be covalently bound to the transition metal complex of the formula IB.

Preferred and very particularly preferred embodiments of the symbols in the transition metal complex of the formula IB have been mentioned above in respect of the transition metal complexes employed in the polymeric materials used according to the invention.

Depending on the substitution pattern on the central metal M¹ of the transition metal complexes of the formula IB and when using a central metal having the coordination number 6, for example Ir(III), the octahedral transition metal complexes can be present in the form of their facial or meridional isomers or as a mixture of facial and meridional isomers in any ratio. Depending on the properties of the facial or meridional isomer of the transition metal complexes of the formula IB, it can be preferable to use either an isomerically pure facial isomer or an isomerically pure meridional isomer or an isomer mixture of facial and meridional isomers in which one of the isomers is present in excess or the isomers are present in equal amounts. The conditions for the formation of facial and meridional isomers have been described above. The present invention thus likewise provides polymeric materials which comprise, apart from fac/mer isomer mixtures, the pure facial or meridional isomers of the transition metal complexes IB of the invention, provided that these can, owing to the substitution pattern, be present on the central metal used. Depending on the properties of the facial or meridional isomer of the transition metal complexes of the formula IB, it can be preferable to use either an isomerically pure facial isomer or an isomerically pure meridional isomer or an isomer mixture of facial and meridional isomers in which one of the isomers is present in excess or the two isomers are present in equal amounts. The individual isomers can be isolated from the corresponding isomer mixture by, for example, chromatography, sublimation or crystallization. Appropriate methods of separating the isomers are known to those skilled in the art.

Preference is given to the group

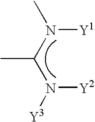

in the transition metal complex IB selected from the group consisting of 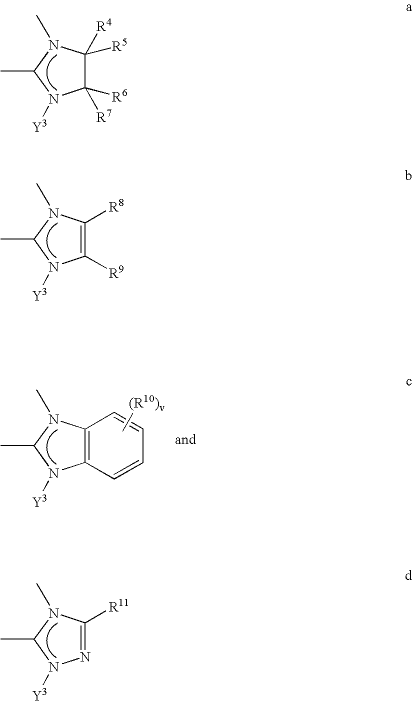
where the symbols have the following meanings:
R⁴, R⁵, R⁶,
R⁷, R⁸, R⁹
and R¹¹ are each hydrogen, alkyl, aryl, heteroaryl, alkenyl or a substituent having a donor or acceptor action which is selected from among halogen radicals, preferably F, Cl, Br, particularly preferably F, alkoxy radicals, aryloxy radicals, carbonyl radicals, ester radicals, amine radicals, amide radicals, CH₂F groups, CHF₂ groups, CF₃ groups, CN groups, thio groups and SCN groups, preferably hydrogen, alkyl, heteroaryl or aryl; where one or two of the radicals R⁴, R⁵, R⁶ or R⁷ in the group of the formula a, one or two of the radicals R⁸ or R⁹ in the group of the formula b and the radical R¹¹ in the group of the formula d can be replaced by one or, in the case of the groups of the formulae a and b, one or two groups capable of bonding covalently to a polymer; with preference being given to one or two of the radicals R⁸ or R⁹ in the group of the formula b and the radical R¹¹ in the group of the formula d being replaced by one or, in the case of the group of the formula b, one or two groups capable of bonding covalently to a polymer;
R¹⁰ is alkyl, aryl, heteroaryl, alkenyl, preferably alkyl or aryl, or 2 radicals R¹⁰ together form a fused-on ring which may contain at least one heteroatom, preferably N, with preference being given to 2 radicals R¹⁰ together forming a fused-on aromatic C₆ ring, where one or more further aromatic rings may be fused onto this, preferably six-membered, aromatic ring, with any conceivable type of fusion being possible, and the fused-on radicals can in turn be substituted; or R¹⁰ is a radical having a donor or acceptor action which is preferably selected from the group consisting of halogen radicals, preferably F, Cl, Br, particularly preferably F; alkoxy groups, aryloxy groups, carbonyl groups, ester groups, amino groups, amide radicals, CHF₂, CH₂F, CF₃, CN, thio groups and SCN;
v is from 0 to 4, preferably 0, 1 or 2, very particularly preferably 0, where, when v is 0, the four carbon atoms of the aryl radical in the formula c which may be substituted by R¹⁰ bear hydrogen atoms and the aryl radical of the group of the formula c may bear, in addition to any radicals R¹⁰ present, one or two groups capable of bonding covalently to a polymer,
Y³ has been defined above.

The group 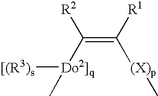
is preferably 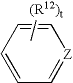
where the symbols have the following meanings:
z is CH or N, with Z being able to be located in the o, m or p position relative to the point of linkage of the group to the carbene ligand;
R¹² is an alkyl, aryl, heteroaryl or alkenyl radical, preferably an alkyl or aryl radical, or 2 radicals R¹² together form a fused-on ring which may contain at least one heteroatom, preferably N, with preference being given to 2 radicals R¹² together forming a fused-on aromatic C₆ ring, where one or more further aromatic rings may be fused onto this, preferably six-membered, aromatic ring, with any conceivable type of fusion being possible, and the fused-on radicals can in turn be substituted; or R¹² is a radical having a donor or acceptor action which is preferably selected from the group consisting of halogen radicals, preferably F, Cl, Br, particularly preferably F; alkoxy groups, aryloxy groups, carbonyl groups, ester groups, amino groups, amide radicals, CHF₂, CH₂F, CF₃, CN, thio groups and SCN;
t is from 0 to 3, where, when t>1, the radicals R¹² can be identical or different, with preference being given to t being 0 or 1, and the group can bear one or two groups capable of bonding covalently to a polymer in addition to any radicals R¹² present.

In the carbene ligands of the formula II, Y³ can be identical to or different from the above-defined group and have the following meanings which have been mentioned above:
a hydrogen atom or an alkyl, aryl, heteroaryl or alkenyl radical, preferably a hydrogen atom or an alkyl, heteroaryl or aryl radical or 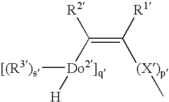
   where Do^{2′}, q′, s′, R^{3′}, R^{1′}, R^{2′}, X′ and p′ independently have the same meanings as Do², q, s, R³, R¹, R², X and p.

Apart from carbene ligands of the formula II in which Y⁴, i.e. the group of the formula 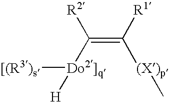
has the structure 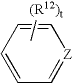
and Y³ is 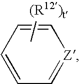
further suitable carbene ligands are ones in which Y⁴, i.e. the group of the formula 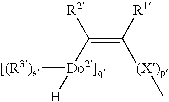
has the structure 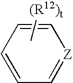
and Y³
is a hydrogen atom or an alkyl, aryl, heteroaryl or alkenyl radical, preferably a hydrogen atom or an alkyl, heteroaryl or aryl radical.

The definitions of the symbols correspond to the definitions given above.

When at least one transition metal complex of the formula IB is bound to the polymer, bonding is preferably via one or more of the carbene ligands of the formula II which have at least one radical of the formula 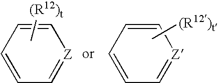
as radical Y³ or Y⁴, with this at least one radical having at least one point of linkage in the polymer. If the transition metal complex of the formula IB is bound via one point of linkage, this is present either on the radical 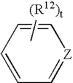
or on the radical

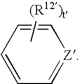

In the case of two points of linkage, both points of linkage can be present on the same radical or each can be present on one of the abovementioned radicals, which is preferred. It is likewise possible for the two points of linkage to be present on two different carbene ligands. They can in each case be present on the same radical, for example in each case on the radical Y³, in the different carbene ligands or on different radicals, for example on the radical Y³ in one carbene ligand and on the radical Y⁴ in the other carbene ligand.

The transition metal complex of the invention particularly preferably has at least two carbene ligands selected independently from the group consisting of 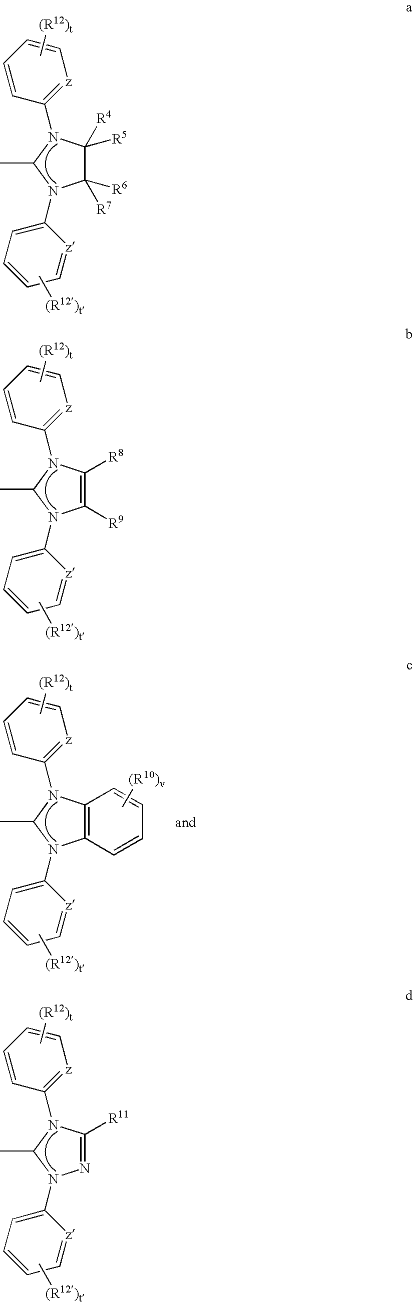
where the symbols have the following meanings:
Z, Z′ are identical or different and are each CH or N;
R¹², R^{12′} are identical or different and are each an alkyl, aryl, heteroaryl or alkenyl radical, preferably an alkyl or aryl radical, or 2 radicals R¹² or R^{12′} together form a fused-on ring which may contain at least one heteroatom, preferably N, with preference being given to 2 radicals R¹² or R^{12′} together forming a fused-on aromatic C₆ ring, where one or more further aromatic rings may be fused onto this, preferably six-membered, aromatic ring, with any conceivable type of fusion being possible, and the fused-on radicals can in turn be substituted; or R¹² or R^{12′} is a radical having a donor or acceptor action, which is preferably selected from the group consisting of halogen radicals, preferably F, Cl, Br, particularly preferably Br or F; alkoxy groups, aryloxy groups, carbonyl groups, ester groups, amino groups, amide radicals, CHF₂, CH₂F, CF₃, CN, aryloxy groups, thio groups and SCN;
t and t′ are identical or different, preferably identical, and are each from 0 to 3, where, when t or t′>1, the radicals R¹² or R^{12′} can be identical or different; t or t¹ is preferably 0 or 1 and when t or t′ is 1, the radical R¹² or R^{12′} is located in the ortho, meta or para position relative to the point of linkage to the nitrogen atom adjacent to the carbene carbon; where the aryl radicals which may bear the radicals R¹² and R^{12′} can bear one or two groups capable of bonding covalently to a polymer in addition to any radicals R¹² and R^{12′}present;
R⁴, R⁵, R⁶,
R⁷, R⁸, R⁹
and R¹¹ are each hydrogen, alkyl, aryl, heteroaryl, alkenyl or a substituent having a donor or acceptor action which is preferably selected from among halogen radicals, preferably F, Cl, Br, particularly preferably F, alkoxy radicals, aryloxy radicals, carbonyl radicals, ester radicals, amine radicals, amide radicals, CH₂F groups, CHF₂ groups, CF₃ groups, CN groups, thio groups and SCN groups, preferably hydrogen, alkyl, heteroaryl or aryl; where one or two of the radicals R⁴, R⁵, R⁶ or R⁷ in the group of the formula a, one or two of the radicals R⁸ or R⁹ in the group of the formula b and the radical R¹¹ in the group of the formula d can be replaced by one or, in the case of the groups of the formulae a and b, one or two groups capable of bonding covalently to a polymer; with preference being given to one or two of the radicals R⁸ or R⁹ in the group of the formula b and the radical R¹¹ in the group of the formula d being replaced by one or, in the case of the group of the formula b, one or two groups capable of bonding covalently to a polymer;
R¹⁰ is alkyl, aryl, heteroaryl or alkenyl, preferably alkyl, heteroaryl or aryl, or 2 radicals R¹⁰ together form a fused-on ring which may contain at least one heteroatom, preferably nitrogen, with preference being given to 2 radicals R¹⁰ together forming a fused-on aromatic C₆ ring, where one or more further aromatic rings may be fused onto this, preferably six-membered, aromatic ring, with any conceivable type of fusion being possible, and the fused-on radicals can in turn be substituted; or R¹⁰ is a radical having a donor or acceptor action which is preferably selected from the group consisting of halogen radicals, preferably F, Cl, Br, particularly preferably F; alkoxy groups, aryloxy groups, carbonyl groups, ester groups, amino groups, amide radicals, CHF₂, CH₂F, CF₃, CN, thio groups and SCN;
v is from 0 to 4, preferably 0, 1 or 2, very particularly preferably 0, where, when v is 0, the four carbon atoms of the aryl radical in the formula c which may be substituted by R¹⁰ bear hydrogen atoms and the aryl radical of the group of the formula c may bear, in addition to any radicals R¹⁰ present, one or two groups capable of bonding covalently to a polymer.

The transition metal complexes of the formula IB particularly preferably have a metal atom M¹ selected from the group consisting of Rh(III), Ir(III), Ru(III), Ru(IV) and Pt(II), preferably Pt(II) or Ir(III). Particular preference is given to using Ir, preferably Ir(III), as metal atom M¹.

In a very particularly preferred embodiment, M¹ in the transition metal complexes of the formula IB is Ir(III), n is 3 and m and o are each 0.

The transition metal complexes of the formula IB can be prepared in a manner analogous to methods known to those skilled in the art. Suitable methods of preparation are described, for example, in the review articles W. A. Hermann et al., Advances in Organometallic Chemistry, Vol. 48, 1 to 69, W. A. Hermann et al., Angew. Chem. 1997, 109, 2256 to 2282 and G. Bertrand et al. Chem. Rev. 2000, 100, 39 to 91, and the references cited therein.

In one embodiment, the functionalized transition metal complexes of the formula III are prepared by deprotonation of the ligand precursors corresponding to the respective carbene ligands and subsequent reaction with suitable metal complexes comprising the desired metal. It is also possible to prepare the transition metal complexes by direct use of Wanzlick olefins.

Suitable ligand precursors are known to those skilled in the art. They are preferably cationic precursors.

Suitable processes for preparing the transition metal complexes of the formula III are carried out in a manner analogous to the processes for preparing transition metal complexes disclosed in the PCT application entitled “Übergangsmetallkomplexe mit Carbenliganden als Emitter für organische Licht-emittierende Dioden (OLEDs)” and having the number “ . . . ” which was filed simultaneously with the present patent application and is therefore not a prior publication. In the preparation, it has to be ensured that one of the ligands K, L or carbene, preferably carbene, bears a radical Q or S.

Especial preference is given to transition metal complexes of the formulae IBa to d selected from the group consisting of 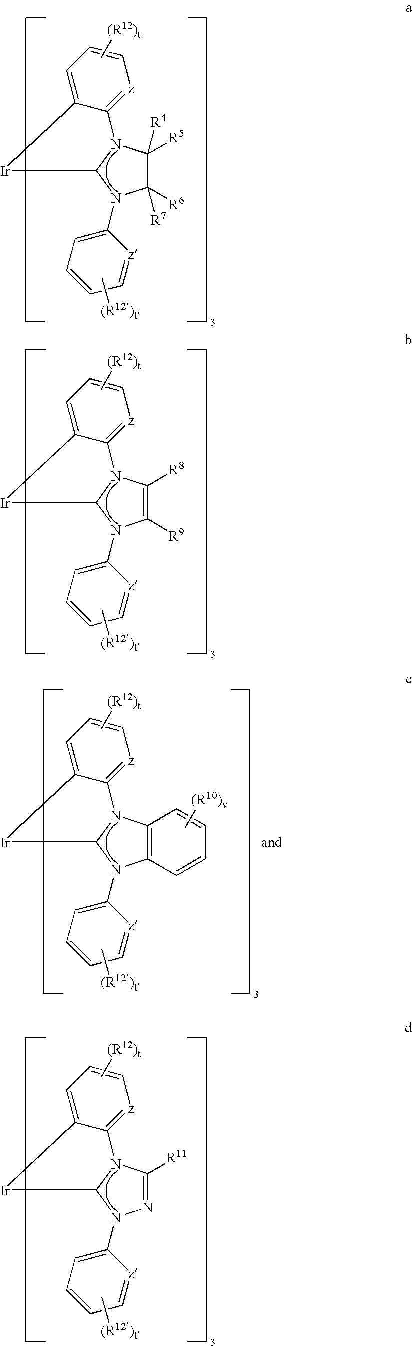
where the symbols have the following meanings:
Z, Z′ are identical or different and are each CH or N;
R¹² , R^{12′} are identical or different and are each an alkyl, aryl, heteroaryl or alkenyl radical, preferably an alkyl or aryl radical, or 2 radicals R ¹² or R^{12′} together form a fused-on ring which may contain at least one heteroatom, preferably N, with preference being given to 2 radicals R¹² or R^{12′} together forming a fused-on aromatic C₆ ring, where one or more further aromatic rings may be fused onto this, preferably six-membered, aromatic ring, with any conceivable type of fusion being possible, and the fused-on radicals can in turn be substituted; or R¹² or R^{12′} is a radical having a donor or acceptor action, which is preferably selected from the group consisting of halogen radicals, preferably F, Cl, Br, particularly preferably Br or F; alkoxy groups, aryloxy groups, carbonyl groups, ester groups, amino groups, amide radicals, CHF₂, CH₂F, CF₃, CN, aryloxy groups, thio groups and SCN;
t and t′ are identical or different, preferably identical, and are each from 0 to 3, where, when t or t′>1, the radicals R¹² or R^{12′} can be identical or different; t or t′ is preferably 0 or 1 and when t or t′ is 1, the radical R¹² or R^{12′} is located in the ortho, meta or para position relative to the point of linkage to the nitrogen atom adjacent to the carbene carbon; where the aryl radicals which may bear the radicals R¹² and R^{12′} can bear one or two groups capable of bonding covalently to a polymer in addition to any radicals R¹² and R^{12′} present;
R⁴, R⁵, R⁶,
R⁷, R⁸, R⁹
and R¹¹ are each hydrogen, alkyl, aryl, heteroaryl, alkenyl or a substituent having a donor or acceptor action which is preferably selected from among halogen radicals, preferably F, Cl, Br, particularly preferably F, alkoxy radicals, aryloxy radicals, carbonyl radicals, ester radicals, amine radicals, amide radicals, CH₂F groups, CHF₂ groups, CF₃ groups, CN groups, thio groups and SCN groups, preferably hydrogen, alkyl, heteroaryl or aryl; where one or two of the radicals R⁴, R⁵, R⁶ or R⁷ in the group of the formula a, one or two of the radicals R⁸ or R⁹ in the group of the formula b and the radical R¹¹ in the group of the formula d can be replaced by one or, in the case of the groups of the formulae a and b, one or two groups capable of bonding covalently to a polymer; with preference being given to one or two of the radicals R⁸ or R⁹ in the group of the formula b and the radical R¹¹ in the group of the formula d being replaced by one or, in the case of the group of the formula b, one or two groups capable of bonding covalently to a polymer;
R¹⁰ is alkyl, aryl, heteroaryl or alkenyl, preferably alkyl, heteroaryl or aryl, or 2 radicals R¹⁰ together form a fused-on ring which may contain at least one heteroatom, preferably nitrogen, with preference being given to 2 radicals R¹⁰ together forming a fused-on aromatic C₆ ring, where one or more further aromatic rings may be fused onto this, preferably six-membered, aromatic ring, with any conceivable type of fusion being possible, and the fused-on radicals can in turn be substituted; or R¹⁰ is a radical having a donor or acceptor action which is preferably selected from the group consisting of halogen radicals, preferably F, Cl, Br, particularly preferably F; alkoxy groups, aryloxy groups, carbonyl groups, ester groups, amino groups, amide radicals, CHF₂, CH₂F, CF₃, CN, thio groups and SCN;
v is from 0 to 4, preferably 0, 1 or 2, very particularly preferably 0, where, when v is 0, the four carbon atoms of the aryl radical in the formula c which may be substituted by R¹⁰ bear hydrogen atoms and the aryl radical of the group of the formula c may bear, in addition to any radicals R¹⁰ present, one or two groups capable of bonding covalently to a polymer.

The polymeric materials of the invention in the form of a mixture of at least one polymer with at least one transition metal complex of the formula IB are prepared by mixing the transition metal complex or complexes of the formula IB with at least one polymer. The present invention therefore further provides a process for preparing the polymeric materials of the invention in the form of a mixture of at least one polymer with at least one transition metal complex of the formula IB by mixing the at least one transition metal complex of the formula IB with at least one polymer. Process conditions and ratios of the components used for preparing mixtures of at least one polymer with at least one transition metal complex of the formula IB have been mentioned above in respect of the preparation of the polymeric materials used according to the invention.

Process conditions, preferred components and ratios of the components used for preparing polymeric materials in which the polymer is covalently bound to the transition metal have been mentioned above in respect of the preparation of the polymeric materials used according to the invention.

The present invention further provides a process for preparing the polymeric materials of the invention in which the polymer is covalently bound to the transition metal by reacting at least one functionalized polymer
“polymer”−(T)_{p′}
with at least one transition metal complex of the formula IIIB which is functionalized by one or more groups Q, 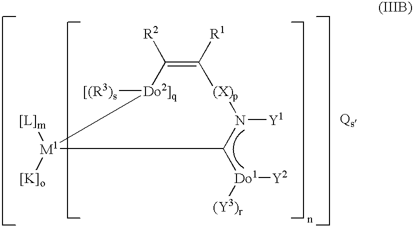
in which the radicals Q are each covalently bound to at least one ligand K, a ligand L or a carbene ligand of the formula II 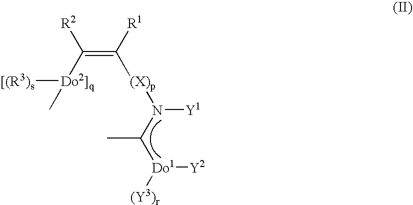
where the symbols have the following meanings:
M¹ is a metal atom selected from the group consisting of Co, Rh, Ir, Nb, Pd, Pt, Fe, Ru, Os, Cr, Mo, W, Mn, Tc, Re, Cu, Ag and Au in any oxidation state possible for the respective metal atom;
L is a monoanionic or dianionic ligand, preferably a monoanionic ligand, which can be monodentate or bidentate;
K is an uncharged monodentate or bidentate ligand;
n is the number of carbene ligands and is at least 2, with the carbene ligands in the complex of the formula IIIB being able to be identical or different;
m is the number of ligands L, where m can be 0 or ≧1 and the ligands L can be identical or different in the case of m>1;
o is the number of ligands K, where o can be 0 or ≧1 and the ligands K can be identical or different in the case of o>1;
   where the sum n+m+o is dependent on the oxidation state and coordination number of the metal atom used and on the number of coordination sites occupied by each of the carbene ligand and the ligands L and K and on the charge on the carbene ligand and the ligand L, with the proviso that n is at least 1, and
Do¹ is a donor atom selected from the group consisting of C, P, N, O and S, preferably P, N, O and S, particularly preferably N;
Do² is a donor atom selected from the group consisting of C, N, P, O and S;
r is 2 when Do¹ is C, is 1 when Do¹ is N or P and is 0 when Do¹ is O or S;
s is 2 when Do² is C, is 1when Do² is N or P and is 0 when Do² is O or S;
X is a spacer selected from the group consisting of silylene, alkylene, arylene, heteroarylene or alkenylene, preferably alkylene or arylene, particularly preferably C₁-C₃-alkylene or C₆-1,4-arylene in which at least one of the four further carbon atoms may be substituted by methyl, ethyl, n-propyl or i-propyl groups or by groups having a donor or acceptor action selected from among halogen radicals, preferably F, Cl, Br, particularly preferably F, alkoxy radicals, aryloxy radicals, carbonyl groups, ester groups, amino groups, amide radicals, CHF₂, CH₂F, CF₃, CN, thio groups and SCN, very particularly preferably methylene, ethylene or 1,4-phenylene;
p is 0 or 1, preferably 0;
q is 0 or 1, preferably 0;
Y¹, Y² together form a bridge between the donor atom Do¹ and the nitrogen atom N which has at least two atoms, preferably two or three atoms, particularly preferably two atoms, of which at least one is a carbon atom and the at least one further atom is preferably a nitrogen atom, with the bridge being able to be saturated or unsaturated, preferably unsaturated, and the at least two atoms of the bridge being able to be substituted or unsubstituted, in which case, if the bridge has two carbon atoms and is saturated, at least one of the two carbon atoms is substituted; the substituents on the groups Y¹ and Y² can together form a bridge having a total of from three to five, preferably four, atoms of which one or two atoms can be heteroatoms, preferably N, and the remaining atoms are carbon atoms, so that Y¹ and Y² together with this bridge form a five- to seven-membered, preferably six-membered, ring which may have two or in the case of a six- or seven-membered ring three double bonds and may be substituted by alkyl or aryl groups and may contain heteroatoms, preferably N, with preference being given to a six-membered aromatic ring which is unsubstituted or substituted by alkyl or aryl groups or is fused with further rings which may contain at least one heteroatom, preferably N, preferably with six-membered aromatic rings;
Y³ is a hydrogen atom or an alkyl, aryl, heteroaryl or alkenyl radical, preferably a hydrogen atom or an alkyl, heteroaryl or aryl radical
   or 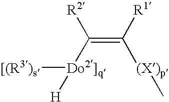
   where Do^{2′}, q′, s′, R^{3′}, R^{1′}, R^{2′}, X′ and p′ independently have the same meanings as Do², q, s, R³, R¹ , R², X and p;
R¹, R² are each, independently of one another, hydrogen or an alkyl, aryl, heteroaryl or alkenyl radical, preferably hydrogen or an alkyl radical, heteroaryl radical or aryl radical;
   or
   R¹ and R² together form a bridge having a total of from three to five, preferably four, atoms of which one or two atoms can be heteroatoms, preferably N, and the remaining atoms are carbon atoms, so that the group 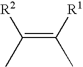
   forms a five- to seven-membered, preferably six-membered, ring which may have, apart from the existing double bond, one or in the case of a six- or seven-membered ring two further double bonds and may be substituted by alkyl or aryl groups and may contain heteroatoms, preferably N, with preference being given to a six-membered aromatic ring which is unsubstituted or substituted by alkyl or aryl groups or is fused with further rings which may contain at least one heteroatom, preferably N, preferably with six-membered aromatic rings;
R³ is hydrogen or an alkyl, aryl, heteroaryl or alkenyl radical, preferably hydrogen or an alkyl, heteroaryl or aryl radical; and
Q and T are radicals capable of being linked to one another to form a covalent bond, where the radical Q is bound to one of the ligands L, K or carbene and the radical T is covalently bound to an end group or central unit of the polymer;
s′ is an integer from 1 to 3, where in the case of s′>1 the group Q is bound to the same ligand or different ligands K, L or carbene, preferably carbene;
p′ is the number of radicals T in the polymer, with p′ being dependent on the molecular weight of the polymer and p′ being selected so that the amount of the transition metal complex used is generally from 0.5 to 50% by weight, preferably from 1 to 30% by weight, particularly preferably from 1 to 20% by weight, based on the total amount of polymer and. transition metal complex, when the polymer itself displays electroluminescence, and when the polymer does not itself display electroluminescence, the amount of the transition metal complex is generally from 5 to 50% by weight, preferably from 10 to 40% by weight, particularly preferably from 15 to 35% by weight, based on the total amount of polymer and transition metal complex.

Q and T are preferably selected from the group consisting of halogen such as Br, I or Cl, alkylsulfonyloxy such as trifluoromethanesulfonyloxy, arylsulfonyloxy such as toluenesulfonyloxy, boron-containing radicals, OH, COOH, activated carboxyl radicals such as acid halides, acid anhydrides or esters, —N≡N⁺X⁻, where X⁻ is a halide, e.g. Cl⁻ or Br⁻, SH, SiR₂″X, and NHR, where R and R″ are each hydrogen, aryl or alkyl, and the abovementioned radicals can be bound directly via a single bond to one of the ligands L, K or carbene, preferably carbene, or to the polymer, or via a linker, —(CR′₂)_{q}—, where the radicals R′ are each, independently of one another, hydrogen, alkyl or aryl and q is from 1 to 15, and one or more methylene groups of the linker —(CR′₂)_{q}— can be replaced by —O—, —S—, —N(R)—, —CON(R)—, —CO—, —C(O)—O—, —O—C(O)—, —CH═CH— or —C≡C—, where R is hydrogen, aryl or alkyl, or via a C₆-C₁₈-arylene group as linker which may be substituted by substituents such as alkyl radicals, aryl radicals, halogen, CN, or NO₂, to one of the ligands L, K or carbene, or to the polymer.

Process conditions, preferred components and ratios of the components used for preparing polymeric materials in which the polymer is covalently bound to the transition metal have been mentioned above in respect of the preparation of the polymeric materials used according to the invention.

The present invention further provides a process for preparing polymeric materials comprising at least one transition metal complex of the formula IIB which is covalently bound to a polymer by copolymerization of monomers having polymerization-active groups with comonomers of the formula IVB 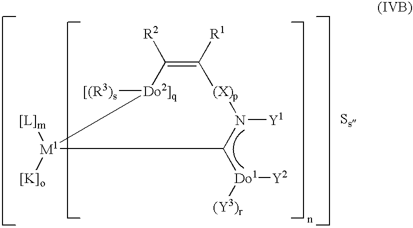
in which S is bound to one or more ligands K, L or a carbene ligand of the formula II 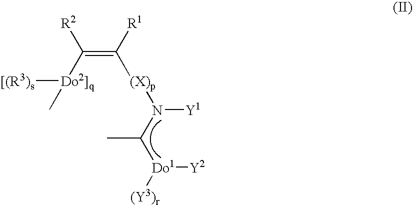
where the symbols have the following meanings:
M¹ is a metal atom selected from the group consisting of Co, Rh, Ir, Nb, Pd, Pt, Fe, Ru, Os, Cr, Mo, W, Mn, Tc, Re, Cu, Ag and Au in any oxidation state possible for the respective metal atom;
L is a monoanionic or dianionic ligand, preferably a monoanionic ligand, which can be monodentate or bidentate;
K is an uncharged monodentate or bidentate ligand;
n is the number of carbene ligands and is at least 2, with the carbene ligands in the complex of the formula I being able to be identical or different;
m is the number of ligands L, where m can be 0 or ≧1 and the ligands L can be identical or different in the case of m>1;
o is the number of ligands K, where o can be 0 or ≧1 and the ligands K can be identical or different in the case of o>1;
   where the sum n+m+o is dependent on the oxidation state and coordination number of the metal atom used and on the number of coordination sites occupied by each of the carbene ligand and the ligands L and K and on the charge on the carbene ligand and the ligand L, with the proviso that n is at least 1, and
Do¹ is a donor atom selected from the group consisting of C, P, N, O and S, preferably P, N, O and S, particularly preferably N;
Do² is a donor atom selected from the group consisting of C, N, P, O and S;
r is 2 when Do¹ is C, is 1 when Do¹ is N or P and is 0 when Do¹ is O or S;
s is 2 when Do² is C, is 1 when Do² is N or P and is 0 when Do² is O or S;
X is a spacer selected from the group consisting of silylene, alkylene, arylene, heteroarylene or alkenylene, preferably alkylene or arylene, particularly preferably C₁-C₃-alkylene or C₆-1,4-arylene in which at least one of the four further carbon atoms may be substituted by methyl, ethyl, n-propyl or i-propyl groups or by groups having a donor or acceptor action selected from among halogen radicals, preferably F, Cl, Br, particularly preferably F, alkoxy radicals, aryloxy radicals, carbonyl groups, ester groups, amino groups, amide radicals, CHF₂, CH₂F, CF₃, CN, thio groups and SCN, very particularly preferably methylene, ethylene or 1,4-phenylene;
p is 0 or 1, preferably 0;
q is 0 or 1, preferably 0;
Y¹, Y² together form a bridge between the donor atom Do¹ and the nitrogen atom N which has at least two atoms, preferably two or three atoms, particularly preferably two atoms, of which at least one is a carbon atom and the at least one further atom is preferably a nitrogen atom, with the bridge being able to be saturated or unsaturated, preferably unsaturated, and the at least two atoms of the bridge being able to be substituted or unsubstituted, in which case, if the bridge has two carbon atoms and is saturated, at least one of the two carbons atoms is substituted; the substituents on the groups Y¹ and Y² can together form a bridge having a total of from three to five, preferably four, atoms of which one or two atoms can be heteroatoms, preferably N, and the remaining atoms are carbon atoms, so that Y¹ and Y² together with this bridge form a five- to seven-membered, preferably six-membered, ring which may have two or in the case of a six- or seven-membered ring three double bonds and may be substituted by alkyl or aryl groups and may contain heteroatoms, preferably N, with preference being given to a six-membered aromatic ring which is unsubstituted or substituted by alkyl or aryl groups or is fused with further rings which may contain at least one heteroatom, preferably N, preferably with six-membered aromatic rings;
Y³ is a hydrogen atom or an alkyl, aryl, heteroaryl or alkenyl radical, preferably a hydrogen atom or an alkyl, heteroaryl or aryl radical
   or 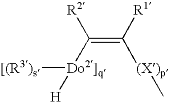
   where Do^{2′}, q′, s′, R^{3′}, R1′, R^{2′}, X′ and p′ independently have the same meanings as Do², q, s, R³, R¹, R², X and p;
R¹, R² are each, independently of one another, hydrogen or an alkyl, aryl, heteroaryl or alkenyl radical, preferably hydrogen or an alkyl radical, heteroaryl radical or aryl radical;
   or
   R¹ and R² together form a bridge having a total of from three to five, preferably four, atoms of which one or two atoms can be heteroatoms, preferably N, and the remaining atoms are carbon atoms, so that the group 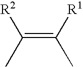
   forms a five- to seven-membered, preferably six-membered, ring which may have, apart from the existing double bond, one or in the case of a six- or seven-membered ring two further double bonds and may be substituted by alkyl or aryl groups and may contain heteroatoms, preferably N, with preference being given to a six-membered aromatic ring which is unsubstituted or substituted by alkyl or aryl groups or is fused with further rings which may contain at least one heteroatom, preferably N, preferably with six-membered aromatic rings;
R³ is hydrogen or an alkyl, aryl, heteroaryl or alkenyl radical, preferably hydrogen or an alkyl, heteroaryl or aryl radical; and
S is a group which can be polymerized with the polymerization-active groups of the monomers and is bound to one of the ligands L, K or carbene, preferably carbene;
s″ is an integer from 1 to 3, where in the case of s″>1 the group S is bound to the same ligand or different ligands K, L or carbene.

Process conditions, preferred components and ratios of the components used for preparing polymeric materials comprising at least one transition metal complex of the formula IIB which is covalently bound to a polymer by copolymerization of monomers having polymerization-active groups with comonomers of the formula IVB have been mentioned above in respect of the preparation of the polymeric materials used according to the invention or are the same as those mentioned above in respect of the preparation of polymeric materials comprising a transition metal complex of the formula II which is covalently bound to a polymer by copolymerization of monomers having polymerization-active groups with comonomers of the formula IV.

The polymeric materials of the invention are particularly suitable for use in organic light-emitting diodes. These organic materials are triplet emitters which have a high energy and power efficiency. Incorporation of the triplet emitters into a polymer makes it possible to apply the polymeric materials of the invention in the form of a film from solution, e.g. by spin coating, inkjet printing or dipping. Thus, the polymeric materials of the invention make it possible to produce large-area displays simply and inexpensively.

The present invention therefore further provides for the use of the polymeric materials used according to the invention or of the polymeric materials of the invention in organic light-emitting diodes (OLEDs). The polymeric materials used according to the invention or the polymeric materials of the invention are preferably used as emitter substances in the OLEDs, since they display emission (electroluminescence) in the visible region of the electromagnetic spectrum. Use of the polymeric materials used according to the invention or the polymeric materials of the invention as emitter substances makes it possible to provide materials which display electroluminescence in the red, green and blue regions of the electromagnetic spectrum. Use of the polymeric materials used according to the invention or the polymeric materials of the invention as emitter substances thus makes it possible to provide industrially usable full-color displays.

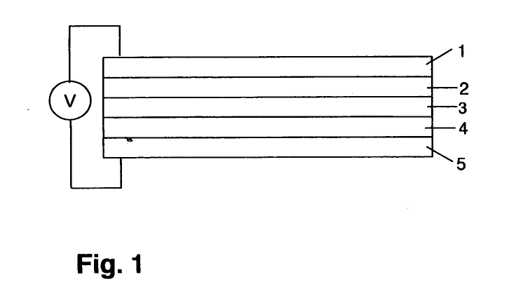

Organic light-emitting diodes are basically made up of a plurality of layers. An example is shown in FIG. 1, in which:
1. anode
2. hole transport layer
3. light-emitting layer
4. electron transport layer
5. cathode

However, it is also possible for not all of the layers mentioned to be present in the OLED; for example, an OLED having the layers (1) (anode), (3) (light-emitting layer) and (5) (cathode) is likewise suitable, with the functions of the layers (2) (hole transport layer) and (4) (electron transport layer) being taken over by the adjoining layers. OLEDs having the layers (1), (2), (3) and (5) or the layers (1), (3), (4) and (5) are like-wise suitable.

The polymeric materials are preferably used as emitter substances in the light-emitting layer. The present invention therefore further provides a light-emitting layer comprising at least one polymeric material as emitter substance. Preferred polymeric materials have been mentioned above.

The abovementioned individual layers of the OLED can in turn be made up of 2 or more layers. For example, the hole transport layer can be made of a layer into which holes are injected from the electrode and a layer which transports the holes away from the hole injection layer to the light-emitting layer. The electron transport layer can like-wise consist of a plurality of layers, for example a layer into which electrons are injected by the electrode and a layer which receives electrons from the electron injection layer and transports them to the light-emitting layer. These layers are each selected according to factors such as energy level, heat resistance and charge carrier mobility and also energy difference between the layers mentioned and the organic layers or the metal electrodes. A person skilled in the art will be able to select the structure of the OLEDs in such a way that it is optimally matched to the polymeric materials used according to the invention as emitter substances.

To obtain particularly efficient OLEDs, the HOMO (highest occupied molecular orbital) of the hole transport layer should be matched to the work function of the anode and the LUMO (lowest unoccupied molecular orbital) of the electron transport layer should be matched to the work function of the cathode.

The present invention further provides an OLED comprising a light-emitting layer according to the invention. The further layers in the OLED can be made up of any material which is customarily used in such layers and is known to those skilled in the art.

The anode (1) is an electrode which provides positive charge carriers. It can, for example, be made up of materials comprising a metal, a mixture of various metals, a metal alloy, a metal oxide or a mixture of various metal oxides. As an alternative, the anode can be a conductive polymer, for example polyaniline or derivatives thereof or polythiophene or derivatives thereof. Suitable metals include the metals of groups 11, 4, 5 and 6 of the Periodic Table of the Elements and the transition metals of groups 8 to 10. If the anode is to be transparent to light, use is generally made of mixed metal oxides of groups 12, 13 and 14 of the Periodic Table of the Elements, for example indium-tin oxide (ITO). It is likewise possible for the anode (1) to comprise an organic material, for example polyaniline, as described, for example, in Nature, Vol. 357, pages 477 to 479 (Jun. 11, 1992). At least one of the anode or cathode should be at least partially transparent to enable the light produced to be emitted.

Suitable hole transport materials for layer (2) of the OLED of the invention are disclosed, for example, in Kirk-Othmer Encyclopedia of Chemical Technology, 4^{th} edition, Vol. 18, pages 837 to 860, 1996. Both hole-transporting molecules and polymers can be used as hole transport material. Customarily used hole-transporting molecules are selected from the group consisting of 4,4′-bis[N-(1-naphthyl)-N-phenylamino]biphenyl (α-NPD), N,N′-diphenyl-N,N′-bis(3-methylphenyl)-[1,1′-biphenyl]-4,4′-diamine(TPD), 1,1-bis[(di-4-tolylamino)phenyl]cyclohexane(TAPC), N,N′-bis(4-methylphenyl)-N,N′-bis(4-ethylphenyl)-[1,1′-(3,3′-dimethyl)biphenyl]-4,4′-diamine(ETPD), tetrakis(3-methylphenyl)-N,N,N′,N′-2,5-phenylenediamine(PDA), α-phenyl-4-N,N-diphenylaminostyrene(TPS), p-(diethylamino)benzaldehyde diphenylhydrazone(DEH), triphenylamine(TPA), bis[4-(N,N-diethylamino)-2-methylphenyl)(4-methylphenyl)methane(MPMP), 1-phenyl-3-[p-(diethylamino)styryl]-5-[p-(diethylamino)phenyl]pyrazoline(PPR or DEASP), 1,2-trans-bis(9H-carbazol-9-yl)cyclobutane(DCZB), N,N,N′,N′-tetrakis(4-methylphenyl)(1,1′-biphenyl)-4,4′-diamine(TTB) and porphyrin compounds and phthalocyanines such as copper phthalocyanines. Customarily used hole-transporting polymers are selected from the group consisting of polyvinylcarbazoles and derivatives thereof, polysilanes and derivatives thereof, for example (phenylmethyl)polysilanes, polyanilines and derivatives thereof, polysiloxanes and derivatives which have an aromatic amine group in the main chain or side chain, polythiophene and derivatives thereof, preferably PEDOT(poly(3,4-ethylenedioxythiophene), particularly preferably PEDOT doped with PSS (polystyrene-sulfonate), polypyrrole and derivatives thereof, poly(p-phenylene-vinylene) and derivatives thereof. Examples of suitable hole transport materials are given, for example, in JP-A 63070257, JP-A 63175860, JP-A 2 135 359, JP-A 2 135 361, JP-A 2 209 988, JP-A 3 037 992 and JP-A 3 152 184. It is likewise possible to obtain hole-transporting polymers by doping polymers such as polystyrene, polyacrylate, poly(meth)acrylate, poly(methyl methacrylate), poly(vinyl chloride), polysiloxanes and polycarbonate with hole-transporting molecules. For this purpose, the hole-transporting molecules are dispersed in the polymers mentioned, which serve as polymeric binders. Suitable hole-transporting molecules are the molecules mentioned above. Preferred hole transport materials are the hole-transporting polymers mentioned. Particular preference is given to polyvinylcarbazoles and derivatives thereof, polysilanes and derivatives thereof, polysiloxane derivatives having an aromatic amino group in their main chain or side chain and polythiophene-containing derivatives, in particular PEDOT-PSS. The preparation of the compounds suitable as hole transport materials is known to those skilled in the art.

Suitable electron-transporting materials for layer (4) of the OLEDs of the invention comprise metals chelated with oxinoid compounds, e.g. tris(8-hydroxyquinolinato)aluminum(Alq₃), compounds based on phenanthroline, e.g. 2,9-dimethyl-4,7-diphenyl-1,10-phenanthroline(DDPA=BCP) or 4,7-diphenyl-1,10-phenanthroline(DPA) and azole compounds such as 2-(4-biphenylyl)-5-(4-t-butylphenyl)-1,3,4-oxadiazole(PBD) and 3-(4-biphenylyl)-4-phenyl-5-(4-t-butylphenyl)-1,2,4-triazole(TAZ), anthraquinonedimethane and derivatives thereof, benzoquinone and derivatives thereof, naphthoquinone and derivatives thereof, fluorenone derivatives, diphenyldicyanoethylene and derivatives thereof, diphenoquinone derivatives, polyquinoline and derivatives thereof, fluorenenone derivatives, diphenyldicyanoethylene and derivatives thereof, diphenoquinone derivatives, polyquinoline and derivatives thereof, polyquinoxaline and derivatives thereof and polyfluorene and derivatives thereof. Examples of suitable electron-transporting materials are disclosed, for example, in JP-A 63070257, JP-A 63 175860, JP-A 2 135 359, JP-A 2 135 361, JP-A 2 209 988, JP-A 3 037 992 and JP-A 3 152 184. Preferred electron-transporting materials are azole compounds, benzoquinone and derivatives thereof, anthraquinone and derivatives thereof, polyfluorene and derivatives thereof. Particular preference is given to 2-(4-biphenyl)-5-(4-t-butylphenyl)-1,3,4-oxadiazole, benzoquinone, anthraquinone, Alq₃, BCP and polyquinoline. The nonpolymeric electron-transporting materials can be mixed with a polymer as polymeric binder. Suitable polymeric binders are polymers which do not display any strong absorption of light in the visible region of the electromagnetic spectrum. Suitable polymers are the polymers mentioned above as polymeric binders in respect of the hole transport materials. The layer (4) can serve either to aid electron transport or as a buffer layer or barrier layer to avoid quenching of the exciton at the boundaries of the layers of the OLED. The layer (4) preferably improves the mobility of electrons and reduces quenching of the exciton.

Some of the materials mentioned above as hole transport materials and electron-transporting materials can perform a number of functions. For example, some of the electron-conducting materials are at the same time hole-blocking materials if they have a low-lying HOMO.

The charge transport layers can also be electronically doped to improve the transport properties of the materials used in order firstly to make the layer thicknesses more generous (avoidance of pinholes/short circuits) and secondly to minimize the operating voltage of the device. For example, the hole transport materials can be doped with electron acceptors: phthalocyanines or arylamines such as TPD or TDTA can, for example, be doped with tetrafluorotetracyanoquinodimethane (F4-TCNQ). The electron-transporting materials can, for example, be doped with alkali metals, for example Alq₃ with lithium. Electronic doping is known to those skilled in the art and is disclosed, for example, in W. Gao, A. Kahn, J. Appl. Phys., Vol. 94, No. 1, Jul. 1, 2003, p-dotierte organische Schichten) and A. G. Werner, F. Li, K. Harada, M. Pfeiffer, T. Fritz, K. Leo, Appl. Phys. Lett., Vol. 82, No. 25, Jun. 23, 2003; Pfeiffer et al., Organic Electronics 2003, 4, 89-103).

The cathode (5) is an electrode which serves to introduce electrons or negative charge carriers. The cathode can be any metal or nonmetal which has a lower work function than the anode. Suitable materials for the cathode are selected from the group consisting of alkali metals of group 1, for example Li, Cs, alkaline earth metals of group 2, metals of group 12 of the Periodic Table of the Elements including the rare earth metals and the lanthanides and actinides. Metals such as aluminum, indium, calcium, barium, samarium and magnesium and combinations (alloys) thereof can also be used.

Furthermore, lithium-containing organometallic compounds or LiF can also be applied between the organic layer and the cathode to reduce the operating voltage.

The OLED of the present invention can further comprise additional layers which are known to those skilled in the art. For example, a layer can be applied between the layer (2) and the light-emitting layer (3) in order to aid transport of the positive charge and/or match the band gap of the layers to one another. As an alternative, this further layer can serve as protective layer. In an analogous way, additional layers can be present between the light-emitting layer (3) and the layer (4) to aid transport of the negative charge and/or match the band gap between the layers to one another. As an alternative, this layer can serve as protective layer.

In a preferred embodiment, the OLED of the invention comprises, in addition to the layers (1) to (5), at least one of the following further layers:
a hole injection layer between the anode (1) and the hole transport layer (2);
a blocking layer for electrons and/or excitons between the hole transport layer (2) and the light-emitting layer (3);
a blocking layer for holes and/or excitons between the light-emitting layer (3) and the electron transport layer (4);
an electron injection layer between the electron transport layer (4) and the cathode (5).

However, it is also possible for not all of the layers mentioned to be present in the OLED; for example, an OLED having the layers (1) (anode), (3) (light-emitting layer) and (5) (cathode) is likewise suitable, with the functions of the layers (2) (hole transport layer) and (4) (electron transport layer) being taken over by the adjoining layers. OLEDs having the layers (1), (2), (3) and (5) or the layers (1), (3), (4) and (5) are like-wise suitable.

A person skilled in the art will know how to select suitable materials (for example on the basis of electrochemical studies). Suitable materials for the individual layers are known to those skilled in the art and are disclosed, for example, in EP-A-1 245 659.

Furthermore, each of the abovementioned layers of the OLED of the invention can be made up of two or more layers. It is also possible for some or all of the layers (1), (2), (3), (4) and (5) to be surface-treated in order to increase the efficiency of charge carrier transport. The choice of materials for each of the layers mentioned is preferably made so as to obtain an OLED having a high efficiency.

The OLED of the invention can be produced by methods known to those skilled in the art. In general, the OLED is produced by successive vapor deposition of the individual layers on a suitable substrate. Suitable substrates are, for example, glass or polymer films. The vapor deposition can be carried out using customary techniques such as thermal vaporization, chemical vapor deposition and others. In an alternative process, the organic layers can be applied from solutions or dispersions in suitable solvents, in particular when polymers are used with coating techniques known to those skilled in the art being employed. Furthermore, printing methods are also suitable for applying the layers, with suitable printing techniques being known to those skilled in the art.

It is not necessary to employ vapor deposition to apply the polymeric materials used according to the invention or the polymeric materials of the invention. The polymeric materials according to the present invention are, in one variant, generally polymerized directly on the previous layer so as to form the desired film (the desired layer) comprising or consisting of at least one polymeric material used according to the invention or the polymeric material of the invention. In a further embodiment, the polymeric materials used according to the invention or the polymeric materials of the invention are applied from solution, with suitable organic solvents being ethers, chlorinated hydrocarbons, for example methylene chloride, and aromatic hydrocarbons, for example methylene chloride, and aromatic hydrocarbons, for example, for example toluene, xylene, chlorobenzene. The application itself can be carried out by means of conventional techniques, for example spin coating, dipping, by film-forming laid coating (screen printing technique), by application using an inkjet printer or by stamp printing, for example by means of PDMS, i.e. stamp printing using a silicone rubber stamp which has been structured photochemically.

In general, the various layers have the following thicknesses: anode (1) from 500 to 5000 Å, preferably from 1000 to 2000 Å; hole transport layer (2) from 50 to 1000 Å, preferably from 200 to 800 Å, light-emitting layer (3) from 10 to 1000 Å, preferably from 100 to 800 Å, electron transport layer (4) from 10 to 1000 Å, preferably from 100 to 800 Å, cathode (6) from 200 to 10,000 Å, preferably from 300 to 5000 Å. The position of the recombination zone of holes and electrons in the OLED of the invention and thus the emission spectrum of the OLED can be influenced by the relative thickness of each layer. This means that the thickness of the electron transport layer should preferably be selected so that the electron/hole recombination zone is located in the light-emitting layer. The ratio of the thicknesses of the individual layers of the OLED is dependent on the materials used. The thicknesses of any additional layers used are known to those skilled in the art.

The use of the polymeric materials used according to the invention or the polymeric materials of the invention as emitter substance in the light-emitting layer of the OLEDs of the invention makes it possible to obtain OLEDs having a high efficiency. The efficiency of the OLEDs of the invention can also be improved by optimizing the other layers. For example, highly efficient cathodes such as Ca, Ba or LiF can be used. Shaped substrates and new charge transport materials which effect a reduction in the operating voltage or an increase in the quantum efficiency can likewise be used in the OLEDs of the invention. Furthermore, additional layers can be present in the OLEDs to adjust the energy level of the various layers and to aid electroluminescence.

The OLEDs of the invention can be used in all devices in which electroluminescence is useful. Suitable devices are preferably selected from among stationary and mobile VDUs. Stationary VDUs are, for example, VDUs of computers, televisions, VDUs in printers, kitchen appliances and advertising signs, lighting and information signs. Mobile VDUs are, for example, VDUs in mobile telephones, laptops, vehicles and destination displays on buses and trains.

Furthermore, the polymeric materials used according to the invention or the polymeric materials of the invention can also be employed in OLEDs having an inverse structure. In these inverse OLEDs, the polymeric materials used according to the invention or the polymeric materials of the invention are once again preferably used in the light-emitting layer. The structure of inverse OLEDs and the materials customarily used therein are known to those skilled in the art.

The following examples illustrate the invention.

### EXAMPLES

1. Preparation of an Emitter Material

a) Preparation of the Ligand

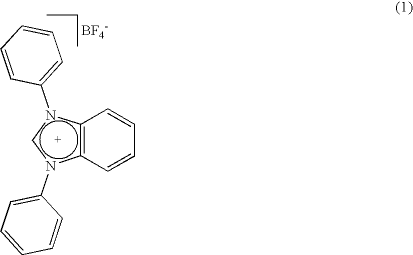

The synthesis starts out from 1,2-phenylenediamine. After introduction of the acetyl groups on the amino functions, the amide obtained was introduced into the phenyl group with the aid of a copper-catalyzed procedure in accordance with the method described in Synthetic Communications, 2000, 30, 3651-3668. Without purification, the material was treated in a boiling ethanolic KOH solution. The product was obtained by chromatography.

¹H-NMR (CD₂Cl₂, 500 MHz): δ=5.70 (s, broad, 2H), 6.87 (t, 2H), 6.93 (d, 4H), 6.97 (dd, 2H), 7.22 (t, 4H), 7.28 (dd, 2H).

The imidazolium salt required was prepared by treating N,N′-diphenylbenzene-1,2-diamine with triethyl orthoformate in the presence of ammonium tetrafluoroborate. The material was obtained by crystallization.

¹H-NMR (DMSO, 400 MHz): δ=7.74-7.84 (m, 8H), 7.91-7.98 (m, 6H), 10.57 (s, 1H).

b) Preparation of an Ir Complex (2)
Synthesis Variant I

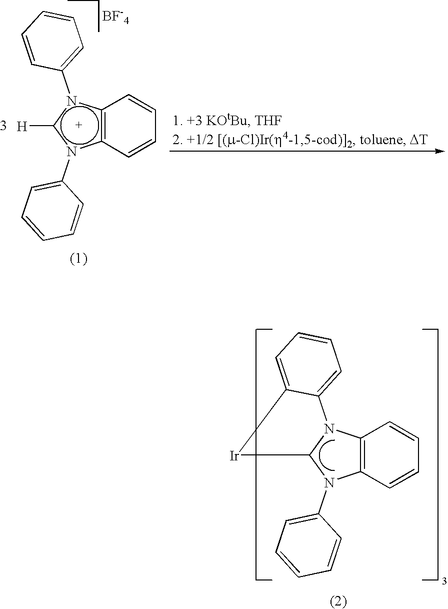

In a 100 ml three-necked flask, 0.99 g (2.8 mmol) of the benzimidazolium salt (compound (3)) was suspended in 20 ml of THF. A solution of 0.32 g of KO^{t}Bu in 10 ml of THF was added to this light-yellow suspension at room temperature. The mixture was stirred at room temperature for 45 minutes and subsequently evaporated to dryness. After taking the residue up in 25 ml of toluene, the resulting suspension was added to a solution of 310 mg of [(μ-Cl)(η⁴-1,5-cod)Ir]₂ (0.46 mmol) in 30 ml of toluene. The mixture was subsequently maintained at room temperature for 15 minutes, heated over-night at 80° C., refluxed for 8 hours, maintained at room temperature over the weekend and refluxed for 5 hours. After cooling, the precipitate was separated off and the filtrate was evaporated. The yellow powder obtained was purified by column chromatography. This gave a white powder (410 mg, 43%).

Synthesis Variant II

1.32 g (3.7 mmol) of the benzimidazolium salt (compound (3)) together with 25 ml of toluene were placed in a 100 ml three-necked flask. At room temperature, 7.5 ml of potassium bistrimethylsilylamide (0.5 M in toluene, 3.7 mmol) were added over a period of 30 minutes and the mixture was stirred at room temperature for 30 minutes. 310 mg (0.46 mmol) of [(μ-Cl)(η⁴-1,5-cod)Ir]₂ were dissolved in 30 ml of toluene, and the salt mixture was added dropwise at room temperature. The mixture was stirred at room temperature for one hour, then at 70° C. for two hours and subsequently overnight under reflux. After filtration, the filtrate was evaporated to dryness and the brown residue was purified by column chromatography. This gave a white powder (0.75 g, 82%).

The Ir complex (2) is formed as a mixture of the kinetically favored meridional (mer) isomer and the thermodynamically favored facial (fac) isomer.

¹H-NMR (fac/mer isomer mixture, data for the main isomer (fac isomer), CDCl₃, 500 MHz): 8.03 (d, 1H), 7.85 (d, 1H), 7.21 (m, 2H), 7.01 (m, 1H), 6.93 (m, 1H), 6.65 (m, 1H), 6.61 (m, 1H), 6.53 (m, 1H), 6.47 (m, 1H), 6.35 (d, 1H), 6.20 (m, 1H), 6.11 (m, 1H), each (CH_{aryl} or NCHCHN). ¹³C-NMR (fac/mer isomer mixture, data for the main isomer (fac isomer), CDCl₃, MHz): 1878 (NCN), 148.8, 147.8, 137.2, 136.9, 131.7 (each C_{q} or IrC_{phenyl}), 135.9, 127.8, 127.3, 127.0, 126.6, 126.4, 123.6, 121.9, 120.8, 120.3, 111.6, 109.9, 109.5 (CH_{aryl}). Mass (fac/mer isomer mixture, EI): m/e=1000.0. Elemental analysis (fac/mer isomer mixture, IrC₅₄H₃₉N₆.¾CH₂Cl₂): C 65.2%, H 3.8%, N 7.9%, Cl 5.0; found: C 64.8%, H 4.0%, N 8.1%, Cl 4.9%. Optical spectroscopy: λ=467 nm (fac/mer isomer mixture, main maximum of the powder).

DTA (fac/mer isomer mixture): Rapid decomposition occurs at about 350° C. when the measurement is carried out in air. Under inert gas, decomposition of the sample commences at about 380° C. (Measurement conditions: in air: 28.0/5.0 (K/min)/750.0, under inert gas: 30.0/5.00 (K/min)/710).

c) Chromatography, Separation of the fac and mer isomers of the Ir Complex of the Formula (2)

2 spots can be seen in the TLC (eluent:toluene), with the fac isomer eluting at R_{F}=0.5 and the mer isomer eluting at about R_{F}=0.35.

0.46 g of the material to be separated was dissolved in toluene by heating to about 30-40° C. with addition of a small amount of CH₂Cl₂.

The two isomers were subsequently separated by chromatography on silica gel (0.063-0.200 mm, J. T. Baker) using toluene as eluent with small fractionation (dimensions of the column: length: 30 cm, diameter: 6 cm).

This gave fac isomer (2a): 0.2886 g

¹H-NMR (CD₂Cl₂, 500 MHz) (fac): δ=8.10 (d, 3H), 7.94 (d, 3H), 7.28 (m, 6H), 7.06 (m, 3H), 7.02 (m, 3H), 6.74 (m, 3H), 6.68 (m, 3H), 6.60 (d, 3H), 6.56 (d, 3H), 6.42 (d, 3H), 6.29 (m, 3H), 6.18 (d, 3H). mer isomer (2b): 0.0364 g

¹H-NMR (CD₂Cl₂, 500 MHz, −20° C.) (mer): δ=8.30 (d, 1H), 7.89 (m, 2H), 7.73 (d, 1H), 7.56 (d, 1H), 7.31 (d, 1H), 7.28-7.16 (m, 5H), 7.08-7.01 (m, 3H), 6.98 (m, 1H), 6.93 (m, 1H), 6.85-6.20 (m, 21H), 5.78 (d, 1H), 5.64 (d, 1H).

2. Preparation of a polymeric Material by Mixing the Transition Metal-carbene Complex of the Formula (2) with a Suitable polymer

A complex of the formula 2 (cf. Examples 1b and 1c) is used as emitter. Polymethyl methacrylate (PMMA) is used as suitable polymer.

To produce the PMMA film, 2 mg of dye (Ir complex (2), Examples 1b and 1c) were dissolved in 1 ml 10% strength (percent by mass) PMMA solution (PMMA in CH₂Cl₂) and a film was applied to a microscope slide by means of a 60 μm doctor blade. The film dries immediately. The measurements in toluene (spectroscopic grade) were carried out at a concentration of 10 mg/l. To remove the oxygen in the solution, nitrogen (O₂ content <150 ppm) was passed through the solution for 5 minutes prior to the measurement and nitrogen was passed over the surface of the liquid during the measurement. All measurements were carried out at room temperature.

3. Production of an OLED Comprising the polymeric Material of the Invention as emitter Layer

The ITO substrate used as anode is firstly cleaned by boiling in isopropanol and acetone. It is treated with ultrasound during this time. The substrates are finally cleaned in a dishwashing machine using commercial cleaners for LCD production (Deconex® 20NS and neutralizing agent 25ORGANACID®). To eliminate any remaining organic residues, the substrate is exposed to a continuous flow of ozone for 25 minutes. This treatment also improves hole injection, since the work function of the ITO is increased.

PEDT:PSS (poly-(3,4-ethylenedioxythiophene)poly(styrenesulfonate))(Baytron® P VP Al 4083) is subsequently applied to the specimen from aqueous solution by spin-coating. A thickness of 46 nm is obtained. This is followed by the emitter layer which is composed of PMMA (polymethyl methacrylate) dissolved in chlorobenzene and the emitter substance (complex 2, Examples 1b and 1c). A two percent strength solution of PMMA in chlorobenzene is used. The dopant (emitter) is added thereto in various concentrations.

After spin coating, the 28% strength solution gives a thickness of about 61 nm and the 40% strength solution gives a thickness of 77 nm. An isomer mixture (fac/mer) (in each case from Example 1b) of the emitter in which the facial isomer represents the main component was used for these solutions. In addition, a 30% strength solution was prepared using the isomerically pure fac emitter (Example 1c). This solution gives a layer thickness of 27 nm after spin coating.

To achieve a better balance of the charge carriers, 40 nm of BCP(2,9-dimethyl-4,7-diphenyl-1,10-phenanthroline) are then applied by vapor deposition. BCP is known for its good electron conductivity, and in addition it blocks holes as a result of its low-lying HOMO, so that the holes can leave the PMMA only with difficulty. Finally, 1 nm of lithium fluoride and 130 nm of aluminum as cathode are deposited.

To characterize the component (OLED), electroluminescence spectra are then recorded at various currents and voltages. Furthermore, the current-voltage curve is measured in combination with the radiated luminous power. The luminous power can then be converted into photometric parameters by calibration using a luminance meter.

The following electrooptical data are obtained in this way for the above-described components (OLEDs):

| | PMMA layer | Emission | Photometric | External | |
|---|---|---|---|---|---|
| Device | thickness | maximum | efficiency | quantum yield | Luminance |
| 28% emitter (complex 2) | 61 nm | 453 nm | 0.8 cd/A | 1% | 30 cd/m² |
| (fac/mer)¹⁾ | | | | | |
| 40% emitter (complex 2) | 77 nm | 453 nm | 0.65 cd/A | 0.75% | 75 cd/m² |
| (fac/mer)¹⁾ | | | | | |
| 30% emitter (complex 2) | 27 nm | 400 nm | 0.53 cd/A | 1.5% | 80 cd/m² |
| (pure fac)²⁾ | | | | | |

¹⁾Example 1b
²⁾Example 1c

1-23. (canceled)

24. Organic light-emitting diodes comprising at least one polymer selected from the group consisting of poly-p-phenylene-vinylene and its derivatives, polythiophene and its derivatives, polyfluorene and its derivatives, polyfluoranthene and its derivatives and polyacetylene and its derivatives, polystyrene and its derivatives, polyacrylates and derivatives thereof, polymethacrylates and derivatives thereof and copolymers comprising the monomer units of the polymers mentioned.
and
at least one transition metal complex of the formula I 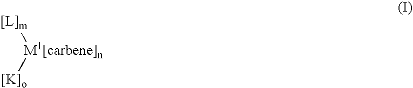
where the symbols have the following meanings:
M¹ is a metal atom selected from the group consisting of Co, Rh, Ir, Nb, Pd, Pt, Fe, Ru, Os, Cr, Mo, W, Mn, Tc, Re, Cu, Ag and Au in any oxidation state possible for the respective metal atom;
carbene is a carbene ligand which may be uncharged or monoanionic and monodentate, bidentate or tridentate and can also be a biscarbene or triscarbene ligand;
L is a monoanionic or dianionic ligand, which can be monodentate or bidentate;
K is an uncharged monodentate or bidentate ligand;
n is the number of carbene ligands and is at least 1, with the carbene ligands in the complex of the formula I being able to be identical or different in the case of n>1;
m is the number of ligands L, where m can be 0 or ≧1 and the ligands L can be identical or different in the case of m>1;
o is the number of ligands K, where o can be 0 or ≧1 and the ligands K can be identical or different in the case of o>1;
where the sum n+m+o is dependent on the oxidation state and coordination number of the metal atom used and on the number of coordination sites occupied by each of the ligands carbene, L and K and on the charge on the ligands carbene and L, with the proviso that n is at least 1; where
the at least one polymer is not poly(N-vinylcarbazole) or polysilane;
in organic light-emitting diodes.

25. Organic light-emitting diodes according to claim 24 comprising mixtures comprising at least one transition metal complex of the formula I and at least one polymer.

26. Organic light-emitting diodes according to claim 24 comprising at least one transition metal complex of the formula I which is covalently bound to at least one polymer.

27. Organic light-emitting diodes according to claim 26, wherein the covalent bonding of the at least one transition metal complex to the polymer occurs via at least one direct covalent linkage between the at least one transition metal complex and the polymer, via a single bond, double bond, a —O—, —S—, —N(R)—, —CON(R)—, —N═N—, —CO—, —C(O)—O— or —O—C(O)— group, where R is hydrogen, alkyl or aryl, or via a linker, a C₁-C₁₅-alkylene group, where one or more methylene groups of the alkylene group can be replaced by —O—, —S—, —N(R)—, —CON(R)—, —CO—, —C(O)—O—, —O—C(O)—, —N═N—, —CH=CH— or —C≡C— to form a chemically feasible radical and the alkylene group can be substituted by alkyl radicals, aryl radicals, halogen, CN or NO₂, where R is hydrogen, alkyl or aryl; or via a C₆-C₁₈-arylene group which may be substituted by alkyl radicals, aryl radicals, halogen, CN or NO₂.

28. Organic light-emitting diodes according to claim 25, wherein the polymeric materials can be prepared by mixing at least one transition metal complex of the formula I with at least one polymer.

29. Organic light-emitting diodes according to claim 26, wherein the polymeric materials can be prepared by reacting at least one functionalized polymer
“polymer”−(T)_{p′}
with at least one transition metal complex of the formula III functionalized with one or more groups Q, where Q is covalently bound to one or more ligands K, a ligand L or a carbene ligand, 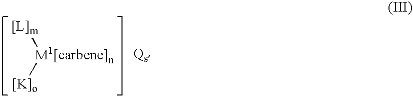
where the symbols have the following meanings:
M¹ is a metal atom selected from the group consisting of Co, Rh, Ir, Nb, Pd, Pt, Fe, Ru, Os, Cr, Mo, W, Mn, Tc, Re, Cu, Ag and Au in any oxidation state possible for the respective metal atom;
carbene is a carbene ligand which may be uncharged or monoanionic and monodentate, bidentate or tridentate and can also be a biscarbene or triscarbene ligand;
L is a monoanionic or dianionic ligand, which can be monodentate or bidentate;
K is an uncharged monodentate or bidentate ligand;
n is the number of carbene ligands and is at least 1, with the carbene ligands in the complex of the formula I being able to be identical or different in the case of n>1;
m is the number of ligands L, where m can be 0 or ≧1 and the ligands L can be identical or different in the case of m>1;
o is the number of ligands K, where o can be 0 or ≧1 and the ligands K can be identical or different in the case of o>1;
where the sum n+m+o is dependent on the oxidation state and coordination number of the metal atom used and on the number of coordination sites occupied by each of the ligands carbene, L and K and on the charge on the ligands carbene and L, with the proviso that n is at least 1, and
Q and T are radicals capable of being linked to one another to form a covalent bond, where the radical Q is bound to one of the ligands L, K or carbene and the radical T is covalently bound to an end group or central unit of the polymer;
s′ is an integer from 1 to 3, where in the case of s′>1 the group Q is bound to the same ligand or different ligands K, L or carbene;
p′ is the number of radicals T in the polymer, with p′ being dependent on the molecular weight of the polymer and p′ being selected so that the amount of the transition metal complex used is generally from 0.5 to 50% by weight, based on the total amount of polymer and transition metal complex, when the polymer itself displays electroluminescence, and when the polymer does not itself display electroluminescence, the amount of the transition metal complex is generally from 5 to 50% by weight, based on the total amount of polymer and transition metal complex.

30. Organic light-emitting diodes according to claim 29, wherein Q and T are selected from the group consisting of halogen, alkylsulfonyloxy, arylsulfonyloxy, boron-containing radicals, OH, COOH, activated carboxyl radicals, —N≡N⁺X⁻, where X⁻ is a halide, SH, SiR₂″X, and NHR, where R and R″ are each hydrogen, aryl or alkyl, and the abovementioned radicals can be bound directly via a single bond to one of the ligands L, K or carbene, or to the polymer, or via a linker, —(CR′₂)_{q}—, where the radicals R′ are each, independently of one another, hydrogen, alkyl or aryl and q is from 1 to 15 and one or more methylene groups of the linker —(CR′₂)_{q}— can be replaced by —O—, —S—, —N(R)—, —CON(R)—, —CO—, —C(O)—O—, —O—C(O)—, —CH═CH— or —C≡C—, where R is hydrogen, aryl or alkyl, or via a C₆-C₁₈-arylene group as linker which may be substituted by alkyl radicals, aryl radicals, halogen, CN, or NO₂, to one of the ligands L, K or carbene, or to the polymer.

31. Organic light-emitting diodes according to claim 26, wherein the polymeric materials comprising at least one transition metal complex of the formula I which is covalently bound to a polymer can be prepared by copolymerization of monomers having polymerization-active groups with comonomers of the formula IV in which S is bound to one or more ligands K, L or carbene, 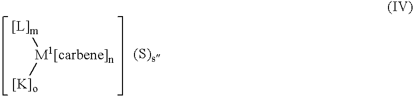
where the symbols have the following meanings:
M¹ is a metal atom selected from the group consisting of Co, Rh, Ir, Nb, Pd, Pt, Fe, Ru, Os, Cr, Mo, W, Mn, Tc, Re, Cu, Ag and Au in any oxidation state possible for the respective metal atom;
carbene is a carbene ligand which may be uncharged or monoanionic and monodentate, bidentate or tridentate and can also be a biscarbene or triscarbene ligand;
L is a monoanionic or dianionic ligand, which can be monodentate or bidentate;
K is an uncharged monodentate or bidentate ligand;
n is the number of carbene ligands and is at least 1, with the carbene ligands in the complex of the formula I being able to be identical or different in the case of n>1;
m is the number of ligands L, where m can be 0 or ≧1 and the ligands L can be identical or different in the case of m>1;
o is the number of ligands K, where o can be 0 or ≧1 and the ligands K can be identical or different in the case of o>1;
where the sum n+m+o is dependent on the oxidation state and coordination number of the metal atom used and on the number of coordination sites occupied by each of the ligands carbene, L and K and on the charge on the ligands carbene and L, with the proviso that n is at least 1;
S is a group which can be polymerized with the polymerization-active groups of the monomers and is bound to one of the ligands L, K or carbene, preferably carbene;
s″ is an integer from 1 to 3, where, when s″>1, the group S is bound to the same ligand or different ligands K, L or carbene.

32. Organic light-emitting diodes according to claim 31, wherein the polymerization-active groups and the groups S which can be polymerized with the polymerization-active groups are selected from the group consisting of formyl groups, phosphonium groups, halogen groups vinyl groups, acryloyl groups, methacryloyl groups, halomethyl groups, acetonitrile groups, alkylsulfonyloxy groups arylsulfonyloxy groups aldehyde groups, OH groups, alkoxy groups, COOH groups, activated carboxyl groups alkylphosphonate groups, sulfonium groups and boron-containing radicals.

33. Organic light-emitting diodes according to claim 32, wherein the groups are selected from among halogen groups, alkylsulfonyloxy groups, arylsulfonyloxy groups and boron-containing groups.

34. Organic light-emitting diodes according to claim 29, wherein the reaction is carried out by means of Suzuki coupling, Kumada coupling or Yamamoto coupling.

35. Organic light-emitting diodes according to claim 24, wherein the polymeric materials are used as emitter substances.

36. A polymeric material comprising
at least one polymer selected from the group consisting of poly-p-phenylene-vinylene and its derivatives, polythiophene and its derivatives, polyfluorene and its derivatives, polyfluoranthene and its derivatives and also polyacetylene and its derivatives, polystyrene and its derivatives, polyacrylates and derivatives thereof, polymethacrylates and derivatives thereof and copolymers comprising monomer units of the polymers mentioned; and
at least one transition metal complex of the formula 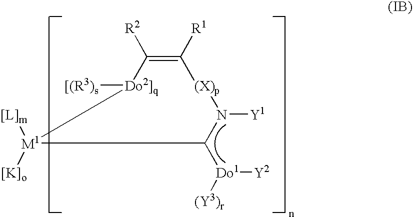
where the symbols have the following meanings:
M¹ is a metal atom selected from the group consisting of Co, Rh, Ir, Nb, Pd, Pt, Fe, Ru, Os, Cr, Mo, W, Mn, Tc, Re, Cu, Ag and Au in any oxidation state possible for the respective metal atom;
L is a monoanionic or dianionic ligand, which can be monodentate or bidentate;
K is an uncharged monodentate or bidentate ligand;
n is the number of carbene ligands and is at least 2, with the carbene ligands in the complex of the formula I being able to be identical or different;
m is the number of ligands L, where m can be 0 or ≧1 and the ligands L can be identical or different in the case of m>1;
o is the number of ligands K, where o can be 0 or ≧1 and the ligands K can be identical or different in the case of o>1;
where
the sum n+m+o is dependent on the oxidation state and coordination number of the metal atom used and on the number of coordination sites occupied by each of the ligands carbene, L and K and on the charge on the ligands carbene and L, with the proviso that n is at least 2;
Do¹ is a donor atom selected from the group consisting of C, P, N, O and S;
Do² is a donor atom selected from the group consisting of C, N, P, O and S;
r is 2 when Do¹ is C, is 1 when Do¹ is N or P and is 0 when Do¹ is O or S;
s is 2 when Do² is C, is 1 when Do¹ is N or P and is 0 when Do² is O or S;
X is a spacer selected from the group consisting of silylene, alkylene, arylene, heteroarylene or alkenylene, in which at least one of the four further carbon atoms may be substituted by methyl, ethyl, n-propyl or i-propyl groups or by groups having a donor or acceptor action selected from among halogen radicals, alkoxy radicals, aryloxy radicals, carbonyl groups, ester groups, amino groups, amide radicals, CHF₂, CH₂F, CF₃, CN, thio groups and SCN;
p is 0 or 1;
q is 0 or 1;
Y¹, Y² together form a bridge between the donor atom Do¹ and the nitrogen atom N which has at least two atoms, of which at least one is a carbon atom and the at least one further atom is a nitrogen atom, with the bridge being able to be saturated or unsaturated, and the at least two atoms of the bridge being able to be substituted or unsubstituted, in which case, of the bridge has two carbon atoms and is saturated, at least one of the two carbon atoms is substituted; the substituents on the groups Y¹ and Y² can together form a bridge having a total of from three to five atoms of which one or two atoms can be heteroatoms and the remaining atoms are carbon atoms, so that Y¹ and Y² together with this bridge form a five- to seven-membered ring which may have two or in the case of a six- or seven-membered ring three double bonds and may be substituted by alkyl or aryl groups and may contain heteroatoms;
Y³ is a hydrogen atom or an alkyl, aryl, heteroaryl or alkenyl radical, or 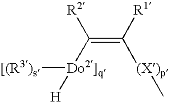
where Do^{2′}, q′, s′, R^{3′}, R^{1′}, R^{2′}, X′ and p′ independently have the same meanings as Do², q, s, R³, R¹, R², X and p;
R¹, R² are each, independently of one another, hydrogen or an alkyl, aryl, heteroaryl or alkenyl radical;
or
R¹ and R² together form a bridge having a total of from three to five, atoms of which one or two atoms can be heteroatoms, and the remaining atoms are carbon atoms, so that the group 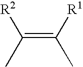
forms a five- to seven-membered, ring which may have, apart from the existing double bond, one or in the case of a six- or seven-membered ring two further double bonds and may be substituted by alkyl or aryl groups and may contain heteroatoms, wherein a six-membered aromatic ring is unsubstituted or substituted by alkyl or aryl groups or is fused with further rings which may contain at least one heteroatom;
R³ is hydrogen or an alkyl, aryl, heteroaryl or alkenyl radical;
where the at least one polymer can be present in the form of a mixture with the transition metal complex of the formula IB or be covalently bound to the transition metal complex of the formula IB.

37. The polymeric material according to claim 36, wherein the transition metal complex of the formula IB is selected from the group consisting of the transition metal complexes of the formulae IBa, IBb, IBc and IBd: 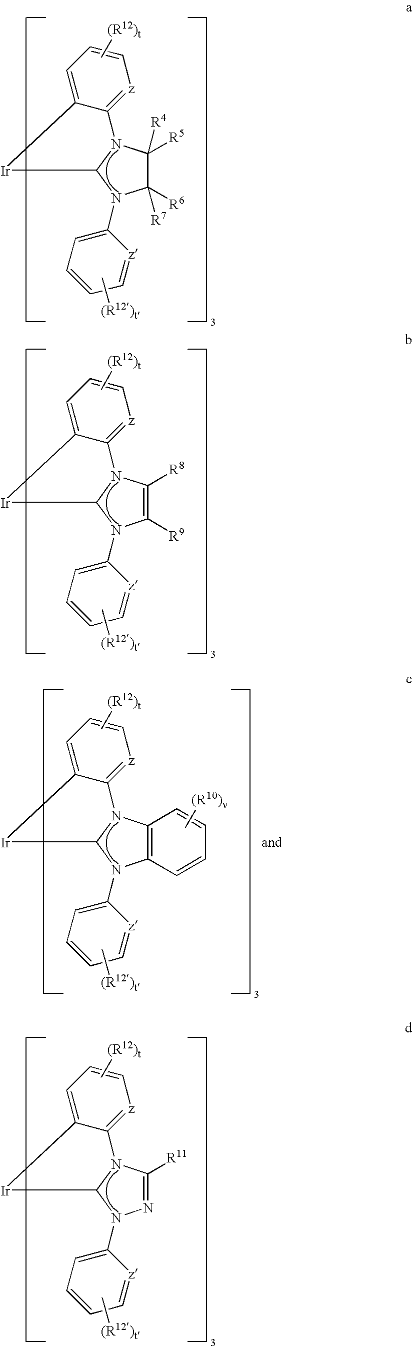
where the symbols have the following meanings:
Z, Z′ are identical or different and are each CH or N;
R¹², R^{12′} are identical or different and are each an alkyl, aryl, heteroaryl or alkenyl radical, or 2 radicals R¹² or R^{12′} together form a fused-on ring which may contain at least one heteroatom, where one or more further aromatic rings may be fused onto this, aromatic ring, with any conceivable type of fusion being possible, and the fused-on radicals can in turn be substituted; or R¹² or R^{12′} is a radical having a donor or acceptor action, which is selected from the group consisting of halogen radicals; alkoxy groups, aryloxy groups, carbonyl groups, ester groups, amino groups, amide radicals, CHF₂, CH₂F, CF₃, CN, aryloxy groups, thio groups and SCN;
t and t′ are identical or different, and are each from 0 to 3, where, when t or t′>1, the radicals R¹² or R^{12′} can be identical or different; and when t or t′ is 1, the radical R¹² or R^{12′} is located in the ortho, meta or para position relative to the point of linkage to the nitrogen atom adjacent to the carbene carbon; where the aryl radicals which may bear the radicals R¹² and R^{12′} can bear one or two groups capable of bonding covalently to a polymer in addition to any radicals R¹² and R^{12′} present;
R⁴, R⁵, R⁶,
R⁷, R⁸, R⁹
and R¹¹ are each hydrogen, alkyl, aryl, heteroaryl, alkenyl or a substituent having a donor or acceptor action which is selected from among halogen radicals, alkoxy radicals, aryloxy radicals, carbonyl radicals, ester radicals, amine radicals, amide radicals, CH₂F groups, CHF₂ groups, CF₃ groups, CN groups, thio groups and SCN groups; where one or two of the radicals R⁴, R⁵, R⁶ or R⁷ in the group of the formula a, one or two of the radicals R⁸ or R⁹ in the group of the formula b and the radical R¹¹ in the group of the formula d can be replaced by one or, in the case of the groups of the formulae a and b, one or two groups capable of bonding covalently to a polymer; with one or two of the radicals R⁸ or R⁹ in the group of the formula b and the radical R¹¹ in the group of the formula d being replaced by one or, in the case of the group of the formula b, one or two groups capable of bonding covalently to a polymer;
R¹⁰ is alkyl, aryl, heteroaryl or alkenyl, or 2 radicals R¹⁰ together form a fused-on ring which may contain at least one heteroatom, with 2 radicals R¹⁰ together forming a fused-on aromatic C₆ ring, where one or more further aromatic rings may be fused onto this, six-membered, aromatic ring, with any conceivable type of fusion being possible, and the fused-on radicals can in turn be substituted; or R¹⁰ is a radical having a donor or acceptor action which is selected from the group consisting of halogen radicals; alkoxy groups, aryloxy groups, carbonyl groups, ester groups, amino groups, amide radicals, CHF₂, CH₂F, CF₃, CN, thio groups and SCN;
v is from 0 to 4, where, when v is 0, the four carbon atoms of the aryl radical in the formula c which may be substituted by R¹⁰ bear hydrogen atoms and the aryl radical of the group of the formula c may bear, in addition to any radicals R¹⁰ present, one or two groups capable of bonding covalently to a polymer.

38. A process for preparing polymeric materials according to claim 36 in the form of a mixture of at least one polymer with at least one transition metal complex of the formula IB by mixing at least one transition metal complex of the formula IB as set forth in claim 36 with at least one polymer as set forth in claim 36.

39. A process for preparing polymeric materials according to claim 36 in which the polymer is covalently bound to the transition metal by reacting at least one functionalized polymer
“polymer”−(T)_{p′}
with at least one transition metal complex of the formula IIIB which is functionalized by one or more groups Q, 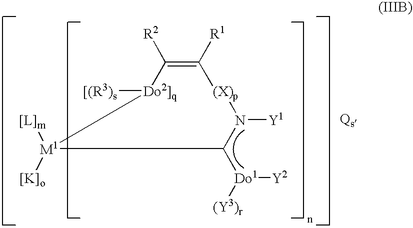
in which the radicals Q are each covalently bound to at least one ligand K, a ligand L or a carbene ligand of the formula II 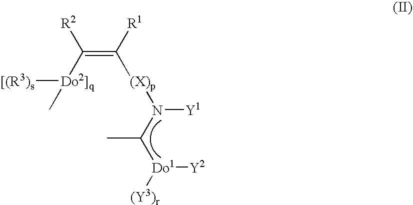
where the symbols have the following meanings:
M¹ is a metal atom selected from the group consisting of Co, Rh, Ir, Nb, Pd, Pt, Fe, Ru, Os, Cr, Mo, W, Mn, Tc, Re, Cu, Ag and Au in any oxidation state possible for the respective metal atom;
L is a monoanionic or dianionic ligand, which can be monodentate or bidentate;
K is an uncharged monodentate or bidentate ligand;
n is the number of carbene ligands and is at least 2, with the carbene ligands in the complex of the formula IIIB being able to be identical or different;
m is the number of ligands L, where m can be 0 or ≧1 and the ligands L can be identical or different in the case of m>1;
o is the number of ligands K, where o can be 0 or ≧1 and the ligands K can be identical or different in the case of o>1;
where the sum n+m+o is dependent on the oxidation state and coordination number of the metal atom used and on the number of coordination sites occupied by each of the carbene ligand and the ligands L and K and on the charge on the carbene ligand and the ligand L, with the proviso that n is at least 2, and
Do¹ is a donor atom selected from the group consisting of C, P, N, O and S;
Do² is a donor atom selected from the group consisting of C, N, P, O and S;
r is 2 when Do¹ is C, is 1 when Do¹ is N or P and is 0 when Do¹ is O or S;
s is 2 when Do² is C, is 1 when Do² is N or P and is 0 when Do² is O or S;
X is a spacer selected from the group consisting of silylene, alkylene, arylene, heteroarylene or alkenylene, in which at least one of the four further carbon atoms may be substituted by methyl, ethyl, n-propyl or i-propyl groups or by groups having a donor or acceptor action selected from among halogen radicals, alkoxy radicals, aryloxy radicals, carbonyl groups, ester groups, amino groups, amide radicals, CHF₂, CH₂F, CF₃, CN, thio groups and SCN;
p is 0 or 1;
q is 0 or 1;
Y¹, Y² together form a bridge between the donor atom Do¹ and the nitrogen atom N which has at least two atoms, of which at least one is a carbon atom and the at least one further atom is a nitrogen atom, with the bridge being able to be saturated or unsaturated, and the at least two atoms of the bridge being able to be substituted or unsubstituted, in which case, if the bridge has two carbon atoms and is saturated, at least one of the two carbon atoms is substituted; the substituents on the groups Y¹ and Y² can together form a bridge having a total of from three to five atoms of which one or two atoms can be heteroatoms and the remaining atoms are carbon atoms, so that Y¹ and Y² together with this bridge form a five- to seven-membered ring which may have two or in the case of a six- or seven-membered ring three double bonds and may be substituted by alkyl or aryl groups and may contain heteroatoms;
Y³ is a hydrogen atom or an alkyl, aryl, heteroaryl or alkenyl radical,
or 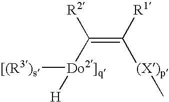
where Do^{2′}, q′, s′, R^{3′}, R^{1′}, R^{2′}, X′ and p′ independently have the same meanings as Do², q, s, R³, R¹, R², X and p;
R¹, R² are each, independently of one another, hydrogen or an alkyl, aryl, heteroaryl or alkenyl radical;
or
R¹ and R² together form a bridge having a total of from three to five, atoms of which one or two atoms can be heteroatoms, and the remaining atoms are carbon atoms, so that the group 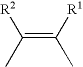
forms a five- to seven-membered, ring which may have, apart from the existing double bond, one or in the case of a six- or seven-membered ring two further double bonds and may be substituted by alkyl or aryl groups and may contain heteroatoms, wherein a six-membered aromatic ring may be unsubstituted or substituted by alkyl or aryl groups or is fused with further rings which may contain at least one heteroatom;
R³ is hydrogen or an alkyl, aryl, heteroaryl or alkenyl radical; and
Q and T are radicals capable of being linked to one another to form a covalent bond, where the radical Q is bound to one of the ligands L, K or carbene and the radical T is covalently bound to an end group or central unit of the polymer;
s′ is an integer from 1 to 3, where in the case of s′>1 the group Q is bound to the same ligand or different ligands K, L or carbene;
p′ is the number of radicals T in the polymer, with p′ being dependent on the molecular weight of the polymer and p′ being selected so that the amount of the transition metal complex used is generally from 0.5 to 50% by weight, based on the total amount of polymer and transition metal complex, when the polymer itself displays electroluminescence, and when the polymer does not itself display electroluminescence, the amount of the transition metal complex is generally from 5 to 50% by weight, based on the total amount of polymer and transition metal complex.

40. The process according to claim 39, wherein Q and T are selected from the group consisting of halogen, alkylsulfonyloxy, arylsulfonyloxy, boron-containing radicals, OH, COOH, activated carboxyl radicals, —N≡N⁺X⁻, where X⁻ is a halide, SH, SiR₂″X, and NHR, where R and R″ are each hydrogen, aryl or alkyl, and the abovementioned radicals can be bound directly via a single bond to one of the ligands L, K or carbene, or to the polymer, or via a linker, —(CR′₂)_{q}—, where the radicals R′ are each, independently of one another, hydrogen, alkyl or aryl and q is from 1 to 15, and one or more methylene groups of the linker —(CR′₂)_{q}— can be replaced by —O—, —S—, —N(R)—, —CON(R)—, —CO—, —C(O)—O—, —O—C(O)—, —CH═CH— or —C≡C—, where R is hydrogen, aryl or alkyl, or via a C₆-C₁₈-arylene group as linker which may be substituted by alkyl radicals, aryl radicals, halogen, CN, or NO₂, to one of the ligands L, K or carbene, or to the polymer.

41. The process according to claim 39 for preparing polymeric materials comprising at least one transition metal complex of the formula IIB which is covalently bound to a polymer by copolymerization of monomers having polymerization-active groups with comonomers of the formula IVB 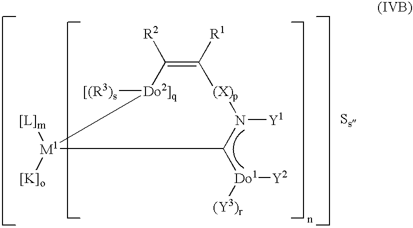
in which S is bound to one or more ligands K, L or a carbene ligand of the formula II 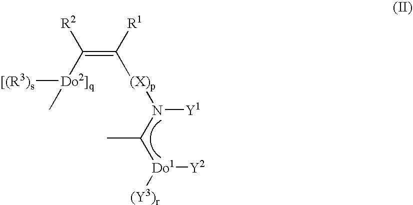
where the symbols have the following meanings:
M¹ is a metal atom selected from the group consisting of Co, Rh, Ir, Nb, Pd, Pt, Fe, Ru, Os, Cr, Mo, W, Mn, Tc, Re, Cu, Ag and Au in any oxidation state possible for the respective metal atom;
L is a monoanionic or dianionic ligand , which can b e monodentate or bidentate;
K is an uncharged monodentate or bidentate ligand;
n is the number of carbene ligands and is at least 2, with the carbene ligands in the complex of the formula I being able to be identical or different;
m is the number of ligands L, where m can be 0 or ≧1 and the ligands L can be identical or different in the case of m>1;
o is the number of ligands K, where o can be 0 or ≧1 and the ligands K can be identical or different in the case of o>1;
where the sum n+m+o is dependent on the oxidation state and coordination number of the metal atom used and on the number of coordination sites occupied by each of the carbene ligand and the ligands L and K and on the charge on the carbene ligand and the ligand L, with the proviso that n is at least 2, and
Do¹ is a donor atom selected from the group consisting of C, P, N, O and S;
Do² is a donor atom selected from the group consisting of C, N, P, O and S;
r is 2 when Do¹ is C, is 1 when Do¹ is N or P and is 0 when Do¹ is O or S;
s is 2 when Do² is C, is 1 when Do² is N or P and is 0 when Do² is O or S;
X is a spacer selected from the group consisting of silylene, alkylene, arylene, heteroarylene or alkenylene, in which at least one of the four further carbon atoms may be substituted by methyl, ethyl, n-propyl or i-propyl groups or by groups having a donor or acceptor action selected from among halogen radicals, alkoxy radicals, aryloxy radicals, carbonyl groups, ester groups, amino groups, amide radicals, CHF₂, CH₂F, CF₃, CN, thio groups and SCN;
p is 0 or 1;
q is 0 or 1;
Y¹,Y² together form a bridge between the donor atom Do¹ and the nitrogen atom N which has at least two atoms, of which at least one is a carbon atom and the at least one further atom is a nitrogen atom, with the bridge being able to be saturated or unsaturated, and the at least two atoms of the bridge being able to be substituted or unsubstituted, in which case, if the bridge has two carbon atoms and is saturated, at least one of the two carbon atoms is substituted; the substituents on the groups Y¹ and Y² can together form a bridge having a total of from three to five atoms of which one or two atoms can be heteroatoms and the remaining atoms are carbon atoms, so that Y¹ and Y² together with this bridge form a five- to seven-membered ring which may have two or in the case of a six- or seven-membered ring three double bonds and may be substituted by alkyl or aryl groups and may contain heteroatoms;
Y³ is a hydrogen atom or an alkyl, aryl, heteroaryl or alkenyl radical,
or 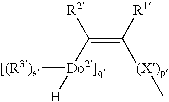
where Do^{2′}, q′, s′, R^{3′}, R^{1′}, R^{2′}, X′ and p′ independently have the same meanings as Do², q, s, R³, R¹, R², X and p;
R¹, R² are each, independently of one another, hydrogen or an alkyl, aryl, heteroaryl or alkenyl radical;
or
R¹ and R² together form a bridge having a total of from three to five, atoms of which one or two atoms can be heteroatoms, and the remaining atoms are carbon atoms, so that the group 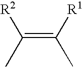
forms a five- to seven-membered, ring which may have, apart from the existing double bond, one or in the case of a six- or seven-membered ring two further double bonds and may be substituted by alkyl or aryl groups and may contain heteroatoms, wherein a six-membered aromatic ring is unsubstituted or substituted by alkyl or aryl groups or is fused with further rings which may contain at least one heteroatom, preferably N;
R³ is hydrogen or an alkyl, aryl, heteroaryl or alkenyl radical; and
S is a group which can be polymerized with the polymerization-active groups of the monomers and is bound to one of the ligands L, K or carbene;
s″ is an integer from 1 to 3, where in the case of s″>1 the group S is bound to the same ligand or different ligands K, L or carbene.

42. The process according to claim 41, wherein the polymerization-active groups and the groups S which can be polymerized with the polymerization-active groups are selected from the group consisting of formyl groups, phosphonium groups, halogen groups, vinyl groups, acryloyl groups, methacryloyl groups, halomethyl groups, acetonitrile groups, alkylsulfonyloxy groups, arylsulfonyloxy groups, aldehyde groups, OH groups, alkoxy groups, COOH groups, activated carboxyl groups, alkylphosphonate groups, sulfonium groups and boron-containing radicals.

43. A light-emitting layer comprising at least one polymeric material as set forth in claim 24.

44. An organic light-emitting diode comprising a light-emitting layer according to claim 43.

45. A device selected from the group consisting of stationary VDUs, VDUs in printers, kitchen appliances and advertising signs, lighting, information signs and mobile VDUs comprising an organic light-emitting diode according to claim 44.

46. A device selected from the group consisting of stationary VDUs, VDUs in printers, kitchen appliances and advertising signs, lighting, information signs and mobile VDUs comprising an organic light-emitting diode according to claim 44.
